(19) United States
(12) Patent Application Publication
(10) Pub. No.: US 2026/0371868 A1
(43) Pub. Date: Nov. 19, 2026

(54) DISPLAY DEVICE AND ELECTRONIC DEVICE INCLUDING THE SAME

(71) Applicant: Samsung Display Co., Ltd., Yongin-si (KR)

(72) Inventors: Jun Ho HWANG, Yongin-si (KR); Hyung Jun AN, Yongin-si (KR)

(73) Assignee: Samsung Display Co., Ltd., Yongin-si (KR)

(21) Appl. No.: 19/404,349

(22) Filed: Dec. 1, 2025

(30) Foreign Application Priority Data
May 14, 2025 (KR) 10-2025-0062763

(51) Int. Cl. H10K 59/131; G09G 3/3266; H10K 59/88

(52) U.S. Cl. CPC H10K 59/131; G09G 3/3266; H10K 59/88; G09G 2300/0819

(57) ABSTRACT

A display device includes: a display panel including one or more pixels, the one or more pixels configured to display an image based on receiving output signals; first pad groups including first pad group output pads, the first pad group output pads configured to deliver first input control signals having a first polarity; second pad groups including second pad group output pads, the second pad group output pads configured to deliver second input control signals having a second polarity, the second polarity different from the first polarity; and a controller overlapping the first pad groups and the second pad groups in a vertical direction perpendicular to an upper surface of the display panel, the controller configured to provide the first input control signals and the second input control signals. The first pad groups are adjacent to each other, and the second pad groups are adjacent to each other.

### CROSS-REFERENCE TO RELATED APPLICATION

This application claims priority under 35 U.S.C. § 119(a) to Korean Patent Application No. 10-2025-0062763, filed on May 14, 2025, in the Korean Intellectual Property Office, the disclosure of which is incorporated herein by reference in its entirety.

### BACKGROUND

### (a) Technical Field

Example embodiments of the present inventive concepts relate to a display device and an electronic device including the same.

### (b) Description of Related Art

As information technology has developed, the importance of display devices, which serve as a medium connecting users and information, has been highlighted. Accordingly, the use of display devices such as liquid crystal display devices, organic light emitting display devices, and the like has increased.

A plurality of pads configured to receive signals which drive pixels of a display panel may be arranged on the display panel. The signals delivered to the plurality of pads may have different polarities, and each pad may form an independent electric field according to the applied signal.

Accordingly, at least one pad of the plurality of pads may be subject to corrosion, and the corrosion on the pads may result in increased resistance, broken wires, short circuits, poor connections, or the like, which may reduce the driving reliability of the display devices.

The foregoing descriptions are only intended to facilitate understanding of the background art of the technical spirits of the present inventive concepts, and therefore, it cannot be understood as corresponding to the prior art known to those skilled in the art.

### SUMMARY

A display device and an electronic device according to some example embodiments of the present inventive concepts are configured to improve the driving reliability of the display device and the electronic device by reducing, minimizing, or preventing corrosion occurring on pads arranged on a display panel.

A display device according to some example embodiments of the present inventive concepts may include: a display panel including one or more pixels, the one or more pixels configured to display an image based on receiving output signals; first pad groups including first pad group output pads, the first pad group output pads configured to deliver first input control signals having a first polarity; second pad groups including second pad group output pads, the second pad group output pads configured to deliver second input control signals having a second polarity, the second polarity different from the first polarity; and a controller overlapping the first pad groups and the second pad groups in a vertical direction perpendicular to an upper surface of the display panel, the controller configured to provide the first input control signals and the second input control signals. The first pad groups are adjacent to each other, and the second pad groups are adjacent to each other.

The display device may further include a scan driver configured to supply a first output signal of the output signals to the display panel. The controller may be configured to provide, to the scan driver via first output pads of the first pad group output pads, clock signals on which the first output signal is based, as the first input control signals.

The scan driver may be configured to supply a second output signal of the output signals to the display panel, and the controller may be configured to provide, to the scan driver via second output pads of the first pad group output pads, initialization clock signals on which the second output signal is based, as the first input control signals.

The display device may further include an emission driver configured to supply a third output signal of the output signals, and the controller may be configured to provide, to the emission driver via first output pads of the second pad group output pads, emission clock signals on which the third output signal is based, as the second input control signals.

The first output pads of the first pad group output pads may be in different rows and columns in one first pad group of the first pad groups, the first output pads of the second pad group output pads may be in different rows and columns in one second pad group of the second pad groups, and the second output pads of the first pad group output pads may be in different rows and columns in another first pad group of the first pad groups.

The first pad groups and the second pad groups may be arranged in one direction.

The first pad groups may include: a (1_1)-th pad group and a (1_2)-th pad group adjacent to each other in the one direction; and one or more dummy pads between a (1_1)-th output pad of the (1_1)-th pad group and a (1_4)-th output pad of the (1_2)-th pad group, with respect to the one direction.

The first pad group output pads and the one or more dummy pads may be arranged in x rows, where x is an integer of 2 or more, and (x−1) dummy pads of the one or more dummy pads may be between the (1_1)-th output pad and the (1_4)-th output pad.

The second pad groups may include a (2_1)-th pad group adjacent to the (1_1)-th pad group in an opposite direction of the one direction, and the one or more dummy pads may be arranged between the (1_1)-th output pad and a (1_7)-th output pad of the (2_1)-th pad group, with respect to the one direction.

The controller may include bumpers in contact with separate, respective output pads of the first pad group output pads and the second pad group output pads.

Each output pad of the first pad group output pads and the second pad group output pads may include: a gate layer configured to deliver one of the first input control signals or the second input control signals; a first insulating layer on the gate layer, the first insulating layer including an opening, the opening exposing the gate layer; a conductive layer on the first insulating layer, the conductive layer in contact with at least a part of the gate layer; and a metal layer overlapping at least a part of the conductive layer, the metal layer electrically connected to one bumper of the bumpers.

Each output pad of the first pad group output pads and the second pad group output pads may further include a wiring layer on a back surface of the gate layer.

A display device according to some example embodiments of the present inventive concepts may include: the display panel including one or more pixels, the one or more pixels configured to display an image based on receiving output signals, the output signals including a first output signal, a second output signal, and a third output signal; a scan driver configured to supply the first output signal and the third output signal to the display panel; an emission driver configured to supply the second output signal to the display panel; a first pad group including first output pads, the first output pads configured to deliver first input control signals to the scan driver based on the first output signal; a second pad group including second output pads, the second output pads configured to deliver second input control signals to the emission driver based on the second output signal; and a third pad group including third output pads, the third output pads configured to deliver third input control signals to the scan driver based on the third output signal. The one or more pixels are configured to operate in a first mode, a second mode, and a third mode sequentially according to the first output signal, the second output signal, and the third output signal, and the first pad group, the second pad group, and the third pad group are arranged in one direction.

The first input control signals and the third input control signals may have a first polarity, and the second input control signals may have a second polarity, the second polarity different from the first polarity.

The first output pads may be in different rows and columns in the first pad group, the second output pads may be in different rows and columns in the second pad group, and the third output pads may be in different rows and columns in the third pad group.

The first pad group may include one or more dummy pads arranged adjacent to one of the first output pads in the one direction.

In the first pad group, the first output pads and the one or more dummy pads may be arranged in x rows, where x is an integer of 2 or more, and (x−1) dummy pads of the one or more dummy pads may be between the first output pads, with respect to the one direction.

An electronic device according to some example embodiments of the present inventive concepts may include: a processor configured to provide input image data, and a display device configured to display an image based on the input image data. The display device may include: a display panel, the display panel including one or more pixels, the one or more pixels configured to display the image based on receiving output signals; first pad groups, the first pad groups including first pad group output pads, the first pad group output pads configured to deliver first input control signals having a first polarity; second pad groups, the second pad groups including second pad group output pads, the second pad group output pads configured to deliver second input control signals having a second polarity, the second polarity different from the first polarity; and a controller overlapping the first pad groups and the second pad groups in a vertical direction perpendicular to an upper surface of the display panel, the controller configured provide the first input control signals and the second input control signals. The first pad groups are adjacent to each other, and the second pad groups are adjacent to each other.

### BRIEF DESCRIPTION OF THE DRAWINGS

FIG. 1 is a block diagram illustrating a display device according to some example embodiments of the present inventive concepts.

FIG. 2 is a diagram illustrating a pixel according to some example embodiments of the present inventive concepts.

FIG. 3 is a plan view of a display device including a display panel, a scan driver, and an emission driver according to some example embodiments of the present inventive concepts.

FIG. 4 is a plan view of a display device according to some example embodiments of the present inventive concepts.

FIG. 5 is a cross-sectional view taken along line I-I′ of FIG. 4 and schematically showing a structure of a pad area according to some example embodiments of the present inventive concepts.

FIG. 6A is a cross-sectional view illustrating a first area of FIG. 5 according to some example embodiments of the present inventive concepts.

FIG. 6B is a cross-sectional view illustrating a first area of FIG. 5 according to some example embodiments of the present inventive concepts.

FIG. 7 is a block diagram illustrating a first scan driver which is a component of a scan driver of FIG. 1 according to some example embodiments of the present inventive concepts.

FIG. 8 is a block diagram illustrating a second scan driver which is a component of a scan driver of FIG. 1 according to some example embodiments of the present inventive concepts.

FIG. 9 is a block diagram illustrating an emission driver of FIG. 1 according to some example embodiments of the present inventive concepts.

FIG. 10 is a timing diagram showing waveforms of a scan start signal, an initialization scan start signal, and an emission start signal according to some example embodiments of the present inventive concepts.

FIG. 11 is a timing diagram showing waveforms of first input control signals according to some example embodiments of the present inventive concepts.

FIG. 12 is a timing diagram showing waveforms of second input control signals according to some example embodiments of the present inventive concepts.

FIG. 13 is a timing diagram showing waveforms of third input control signals according to some example embodiments of the present inventive concepts.

FIG. 14 is a plan view of an example of a pad area according to some example embodiments of the present inventive concepts.

FIG. 15 is a plan view of an example of a pad area according to some example embodiments of the present inventive concepts.

FIG. 16 is a plan view of an example of a pad area according to some example embodiments of the present inventive concepts.

FIG. 17 is a plan view of an example of a pad area according to some example embodiments of the present inventive concepts.

FIG. 18 is a block diagram of an electronic device according to some example embodiments of the present inventive concepts.

FIG. 19 illustrates schematic diagrams of an electronic device according to some example embodiments of the present inventive concepts.

### DETAILED DESCRIPTION

Hereinafter, some example embodiments according to the present inventive concepts are described in detail with reference to the accompanying drawings. It should be noted that in the following description, only portions necessary for understanding an operation according to the present inventive concepts may be described, and descriptions of other portions may be omitted in order not to obscure the subject matter of the present inventive concepts. In addition, the present inventive concepts may be embodied in other forms without being limited to some example embodiments described herein. However, embodiments of the present inventive concepts are described in detail in order for those skilled in the art to be able to readily implement the technical spirit of the present inventive concepts.

Throughout the specification, in a case where a component is “connected” to another component, the components may be “directly connected” or the components may be “indirectly connected” with another element interposed therebetween. Terms used herein are for describing specific embodiments and are not intended to limit the present inventive concepts. Throughout the specification, in a case where a certain portion “includes” a certain component, the portion may further include another component without excluding another component unless otherwise stated. “At least one of X, Y, and Z” and “at least one selected from a group consisting of X, Y, and Z” may be interpreted as X only, Y only, Z only, or any combination of two or more of X, Y, and Z (for example, XYZ, XYY, YZ, and ZZ). Here, “and/or” includes all combinations of one or more of corresponding configurations.

Here, terms such as first and second may be used to describe various components, but these components are not limited to these terms. These terms are used to distinguish one component from another component. Therefore, a first component may refer to a second component within a range without departing from the scope disclosed herein.

Spatially relative terms such as “under”, “on”, and the like may be used for descriptive purposes, thereby describing a relationship between one element or feature and another element(s) or feature(s) as shown in the drawings. Spatially relative terms are intended to include other directions in use, in operation, and/or in manufacturing, in addition to the direction depicted in the drawings. For example, when a device shown in the drawing is turned upside down, elements depicted as being positioned “under” other elements or features may be positioned in a direction “on” the other elements or features. Therefore, in some example embodiments, the term “under” may include both directions of on and under. In addition, the device may face in other directions (for example, rotated 90 degrees or in other directions) and thus the spatially relative terms used herein may be interpreted according thereto.

In addition, example embodiments of the inventive concepts may be described here with reference to schematic diagrams (and intermediate structures) of the present inventive concepts, so that changes in a shape as shown due to, for example, manufacturing technology and/or a tolerance may be expected. Therefore, example embodiments described herein may not be construed as being limited to the specific shapes shown in the drawings, and should be interpreted as including, for example, changes in shapes that occur as a result of manufacturing. As described herein, the shapes shown in the drawings may not show actual shapes of areas of a device, and example embodiments are not limited thereto.

It will be understood that elements and/or properties thereof (e.g., structures, surfaces, directions, or the like), which may be referred to as being “perpendicular,” “parallel,” or the like with regard to other elements and/or properties thereof (e.g., structures, surfaces, directions, or the like) may be “perpendicular,” “parallel,” or the like or may be “substantially perpendicular,” “substantially parallel,” or the like, respectively, with regard to the other elements and/or properties thereof.

Elements and/or properties thereof (e.g., structures, surfaces, directions, or the like) that are “substantially perpendicular” or “substantially parallel” with regard to other elements and/or properties thereof will be understood to be “perpendicular” or “parallel”, respectively, with regard to the other elements and/or properties thereof within manufacturing tolerances and/or material tolerances and/or have a deviation in magnitude and/or angle from “perpendicular” or “parallel”, respectively, with regard to the other elements and/or properties thereof that is equal to or less than 10% (e.g., a. tolerance of ±10%).

It will be understood that elements and/or properties thereof may be recited herein as being “the same” as other elements and/or properties thereof, and it will be further understood that elements and/or properties thereof recited herein as being “the same” as other elements and/or properties thereof may be “the same” as or “substantially the same” as the other elements and/or properties thereof. Elements and/or properties thereof that are “substantially the same” as other elements and/or properties thereof will be understood to include elements and/or properties thereof that are the same as the other elements and/or properties thereof within manufacturing tolerances and/or material tolerances. Elements and/or properties thereof that are the same or substantially the same as other elements and/or properties thereof may be structurally the same or substantially the same, functionally the same or substantially the same, and/or compositionally the same or substantially the same.

While the term “same” may be used in description of some example embodiments, it should be understood that some imprecisions may exist. Thus, when one element or property is referred to as being the same as another element or property, it should be understood that the element or property is the same as another element or property within a desired manufacturing or operational tolerance range (e.g., ±10%).

It will be understood that elements and/or properties thereof described herein as being “substantially” the same as one or more other elements and/or properties thereof encompasses elements and/or properties thereof that have a relative difference in magnitude with the one or more other elements and/or properties thereof that is equal to or less than 10%. Further, regardless of whether elements and/or properties thereof are modified as “substantially,” it will be understood that these elements and/or properties thereof should be construed as including a manufacturing or operational tolerance (e.g., ±10%) around the stated elements and/or properties thereof.

When the terms “about” or “substantially” are used in this specification in connection with a numerical value, it is intended that the associated numerical value includes a manufacturing or operational tolerance (e.g., ±10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

As described herein, when an operation is described to be performed, or an effect such as a structure is described to be established “by” or “through” performing additional operations, it will be understood that the operation may be performed and/or the effect/structure may be established “based on” the additional operations, which may include performing said additional operations alone or in combination with other further additional operations.

As described herein, an element that is described to be “spaced apart” from another element, in general and/or in a particular direction (e.g., vertically spaced apart, laterally spaced apart, etc.) and/or described to be “separated from” the other element, may be understood to be isolated from direct contact with the other element, in general and/or in the particular direction (e.g., isolated from direct contact with the other element in a vertical direction, isolated from direct contact with the other element in a lateral or horizontal direction, etc.). Similarly, elements that are described to be “spaced apart” from each other, in general and/or in a particular direction (e.g., vertically spaced apart, laterally spaced apart, etc.) and/or are described to be “separated” from each other, may be understood to be isolated from direct contact with each other, in general and/or in the particular direction (e.g., isolated from direct contact with each other in a vertical direction, isolated from direct contact with each other in a lateral or horizontal direction, etc.). Similarly, a structure described herein to be between two other structures to separate the two other structures from each other may be understood to be configured to isolate the two other structures from direct contact with each other.

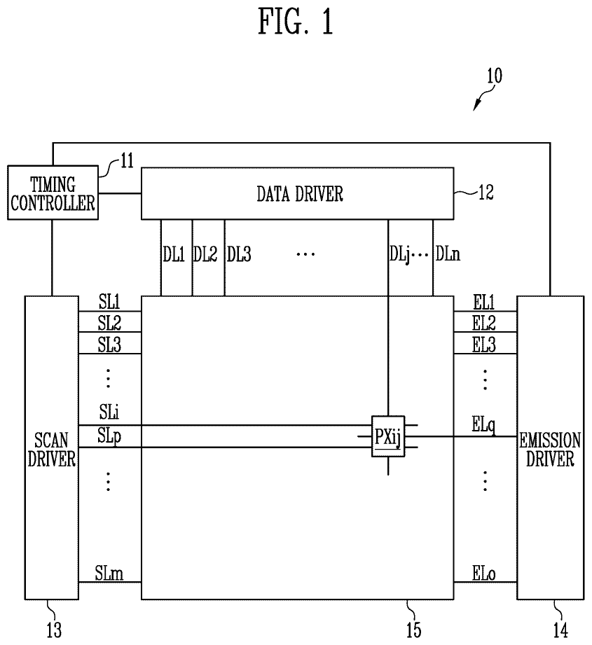

FIG. 1 is a block diagram illustrating a display device 10 according to some example embodiments of the present inventive concepts.

Referring to FIG. 1, the display device 10 according to some example embodiments of the present inventive concepts may include a timing controller 11, a data driver 12, a scan driver 13, an emission driver 14, and a display panel 15.

The timing controller 11 may receive, from a processor, input image data, including for example grayscales and control signals for each image frame. The timing controller 11 may provide control signals suitable for a respective specification to the data driver 12, the scan driver 13, the emission driver 14, and the like, for displaying an image corresponding to the image frame.

The data driver 12 may generate data voltages to be provided to data lines DL1, DL2, DL3, . . . , DLj, . . . , DLn by using the grayscales and control signals. For example, the data driver 12 may sample the grayscales using a clock signal and apply data voltages corresponding to the grayscales to the data lines DL1 to DLn in pixel row units. In some example embodiments, j and n may each independently be a positive integer, where j may be any integer greater than 0 and n may be any integer greater than j.

The scan driver 13 may receive a clock signal, a scan start signal, and the like from the timing controller 11 and generate scan signals to be provided to first to m-th scan lines SL1 to SLm, where m may be any integer greater than 1.

The scan driver 13 may provide the scan signals to the first to m-th scan lines SL1 to SLm. For example, the scan driver 13 may sequentially provide scan signals having a turn-on level pulse. The scan driver 13 may include scan stages (or, scan stage circuits) configured in the form of shift registers. For example, the scan driver 13 may generate scan signals by sequentially delivering a scan start signal in the form of a turn-on level pulse to a next scan stage under the control of scan clock signals.

The emission driver 14 may provide light emitting signals to emission lines EL1 to ELo, where o may be any integer of 1 or more. For example, the emission driver 14 may sequentially supply emission signals having a turn-off level pulse. The emission driver 14 may include emission stages (or, emission stage circuits) configured in the form of shift registers. For example, the emission driver 14 may generate light emitting signals by sequentially delivering an emission stop signal in the form of a turn-off level pulse to a next emission stage under the control of emission clock signals.

The display panel 15 may include one or more pixels, or a plurality of pixels. Each pixel may be connected to at least two of the scan lines SL1 to SLm and at least one of the emission lines EL1 to ELo. Further, each pixel may be connected to at least one data line. For example, a pixel PXij may be connected to an i-th scan line SLi, a p-th scan line SLp, a q-th emission line ELq, and a j-th data line DLj.

A pixel row may be defined as a set of pixels connected to the same scan lines and emission line. For example, an i-th pixel row may be defined as pixels connected to the i-th scan line SLi, the p-th scan line SLp, and the q-th emission line ELq. The i-th pixel row includes the ij-th pixel PXij. The pixels which constitute the i-th pixel row may be connected to different data lines.

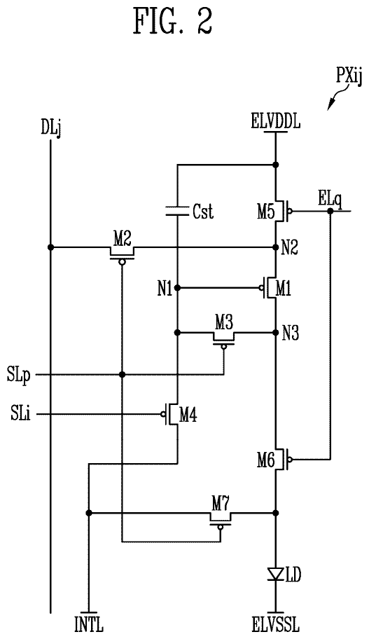

FIG. 2 is a diagram illustrating the pixel PXij according to some example embodiments of the present inventive concepts.

Referring to FIG. 2, the pixel PXij includes first to seventh transistors M1, M2, M3, M4, M5, M6, and M7, a storage capacitor Cst, and a light emitting diode LD.

Hereinafter, a circuit including a P-type transistor is described as an example. However, those skilled in the art would be able to design a circuit including an N-type transistor by varying polarity of a voltage applied at a gate terminal. Similarly, those skilled in the art would also be able to design a circuit including a combination of a P-type transistor and an N-type transistor. A P-type transistor collectively refers to a transistor in which the amount of a current increases when a voltage difference between a gate electrode and a source electrode increases in the negative direction. An N-type transistor collectively refers to a transistor in which the amount of a current increases when a voltage difference between a gate electrode and a source electrode increases in the positive direction. Transistors can be configured in various forms, such as a thin film transistor (TFT), a field effect transistor (FET), or a bipolar junction transistor (BJT).

The first transistor M1 may have a gate electrode connected to a first node N1, a first electrode connected to a second node N2, and a second electrode connected to a third node N3. For example, the first transistor M1 may operate as a driving transistor.

The second transistor M2 may have a gate electrode connected to the p-th scan line SLp, a first electrode connected to the data line DLj, and a second electrode connected to the second node N2. For example, the second transistor M2 may operate as a scan transistor.

The third transistor M3 may have a gate electrode connected to the p-th scan line SLp, a first electrode connected to the first node N1, and a second electrode connected to the third node N3. For example, the third transistor M3 may operate as a diode-connected transistor.

The fourth transistor M4 may have a gate electrode connected to the i-th scan line SLi, a first electrode connected to the first node N1, and a second electrode connected to an initialization line INTL. For example, the fourth transistor M4 may operate as a gate initialization transistor.

In some example embodiments, the gate electrode of the fourth transistor M4 may be connected to another scan line. For example, the gate electrode of the fourth transistor M4 may be connected to the p-th scan line SLp or the i-th scan line SLi.

The fifth transistor M5 may have a gate electrode connected to the q-th emission line ELq, a first electrode connected to a first power line ELVDDL, and a second electrode connected to the second node N2. For example, the fifth transistor M5 may operate as a first emission transistor. In some example embodiments, the gate electrode of the fifth transistor M5 may be connected to another emission line.

The sixth transistor M6 may have a gate electrode connected to the q-th emission line ELq, a first electrode connected to the third node N3, and a second electrode connected to an anode electrode of the light emitting diode LD. The sixth transistor M6 may operate as a second emission transistor. In some example embodiments, the gate electrode of the sixth transistor M6 may be connected to another emission line.

The seventh transistor M7 may have a gate electrode connected to the p-th scan line SLp, a first electrode connected to the initialization line INTL, and a second electrode connected to the anode electrode of the light emitting diode LD. The seventh transistor M7 may operate as an anode initialization transistor. In some example embodiments, the gate electrode of the seventh transistor M7 may be connected to another scan line. For example, the gate electrode of the seventh transistor M7 may be connected to the i-th scan line SLi.

A first electrode of the storage capacitor Cst may be connected to the first power line ELVDDL, and a second electrode may be connected to the first node N1.

The light emitting diode LD may have an anode electrode connected to the second electrode of the sixth transistor M6, and a cathode electrode connected to a second power line ELVSSL. The light emitting diode LD may include an organic light emitting diode, an inorganic light emitting diode, a quantum dot/well light emitting diode, or the like. In addition, the light emitting diode LD may include a plurality of light emitting diodes connected in series, parallel, or in series and parallel.

A first power voltage may be applied to the first power line ELVDDL, a second power voltage may be applied to the second power line ELVSSL, and an initialization voltage may be applied to the initialization line INTL. For example, the first power voltage may be greater than the second power voltage. For example, the initialization voltage may be equal to or greater than the second power voltage.

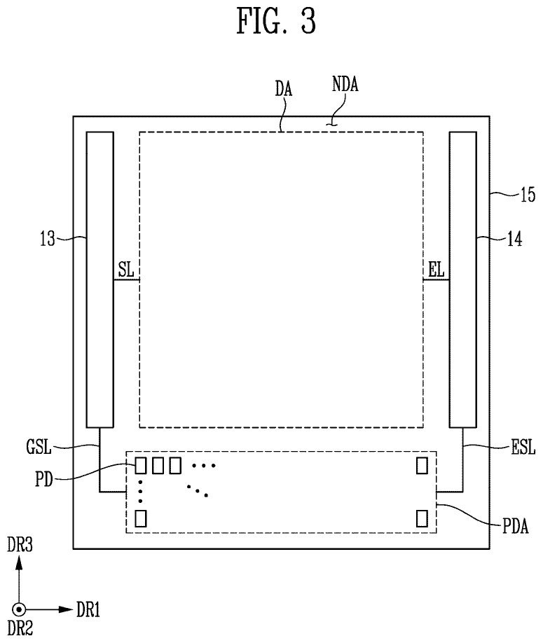

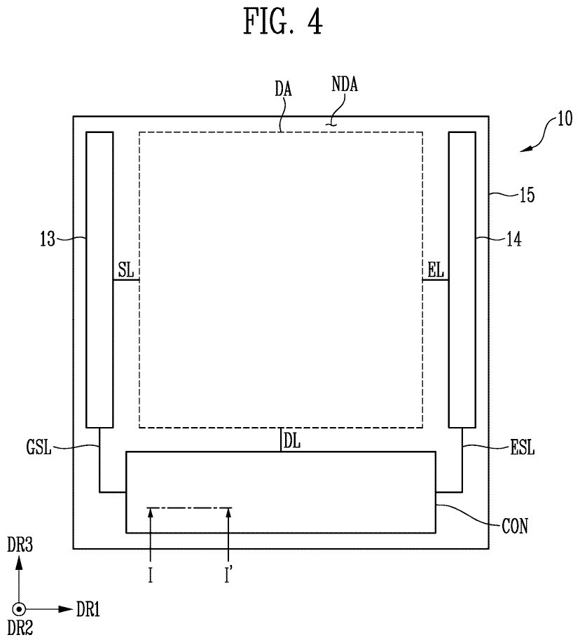

FIG. 3 is a plan view of a display device 10 including the display panel 15, the scan driver 13, and the emission driver 14 according to some example embodiments of the present inventive concepts. FIG. 4 is a plan view of the display device 10 according to some example embodiments of the present inventive concepts. The display device 10 shown in FIG. 4 may be the display device 10 shown in FIG. 3, and the display device shown in FIG. 3 and/or FIG. 4 may be the display device 10 shown in FIG. 1.

Referring to FIG. 3, the display panel 15 may be an emissive display panel. According to some example embodiments, the display panel 15 may be an organic light-emitting display panel or a quantum dot light-emitting display panel. An organic light-emitting display panel has an emission layer including an organic light-emitting material. A quantum dot light-emitting display panel has an emission layer including a quantum dot and a quantum rod. Hereinafter, for convenience of description, the display panel 15 is described as an organic light-emitting display panel.

The display panel 15 includes a display area DA and a non-display area NDA adjacent to the display area DA. The non-display area NDA is an area in which no image is displayed. In an example, the display area DA may be defined as an area in which one or more pixels (e.g., a plurality of pixels) are arranged to provide image information to a user. For example, the display panel 15 may include (e.g., in the display area DA) one or more pixels (e.g., PXij as shown in FIG. 1) configured to display an image based on receiving output signals. The non-display area NDA is a peripheral area of the display area DA and may surround the display area DA.

The non-display area NDA may be defined as an area in which the wiring and electronic components to drive one or more pixels of the display panel 15 are placed. For example, the scan driver 13 and the emission driver 14 may be placed on the non-display area NDA.

The scan driver 13 and the emission driver 14 of FIG. 3 may be described similarly to the scan driver 13 and the emission driver 14 of FIG. 1. According to some example embodiments, the scan driver 13 and the emission driver 14 may be implemented in a single component.

The display panel 15 may be connected to the scan driver 13 via a scan line SL. The display panel 15 may be connected to the emission driver 14 via an emission line EL. The scan line SL of FIG. 3 may be one of the scan lines SL1 to SLm of FIG. 1. The emission line EL of FIG. 3 may be one of the emission lines EL1 to ELo of FIG. 1.

The non-display area NDA may include a pad area PDA. A plurality of pads (or, output pads) PD may be arranged in the pad area PDA. For example, the plurality of pads PD may be arranged in a first direction DR1 in the pad area PDA. The display panel 15 may receive an electrical signal from an external source (e.g., a controller CON) via the plurality of pads PD.

The pads PD may be arranged in the pad area PDA in the first direction DR1 and a third direction DR3. The pads PD may be arranged in three rows. However, this is only an example and the present inventive concepts are not limited thereto. For example, the pads PD may be arranged in two rows or four rows.

The pads PD may be connected to the scan driver 13 via the scan line SL. For example, the pads PD may deliver (transmit) input control signals which cause the scan driver 13 to output scan signals.

The pads PD may be connected to the emission driver 14 via the emission line EL. For example, the pads PD may deliver input control signals which cause the emission driver 14 to output light emitting signals.

Referring to FIGS. 3 and 4, the display device 10 may include a controller CON. The controller CON may be placed in the pad area PDA.

The controller CON may include the timing controller 11 and the data driver 12 of FIG. 1. For example, the controller CON may generate and provide (transmit) control signals suitable for the scan driver 13 and the emission driver 14. For example, the controller CON can supply a scan driving signal to the scan driver 13 via the pads PD and a scan control line GSL. In addition, the controller CON can supply (transmit) an emission driving signal to the emission driver 14 via the pads PD and an emission control line ESL. The controller CON may provide a data voltage to the pixels of the display panel 15. However, this is only an example and the present inventive concepts are not limited thereto.

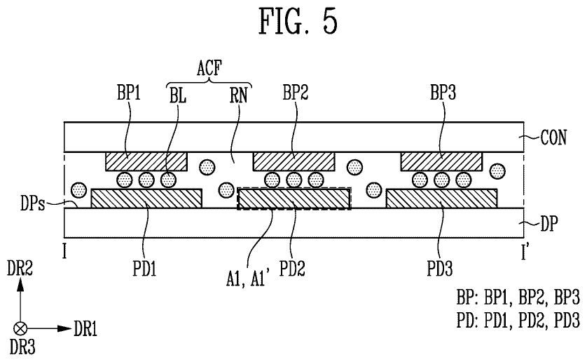

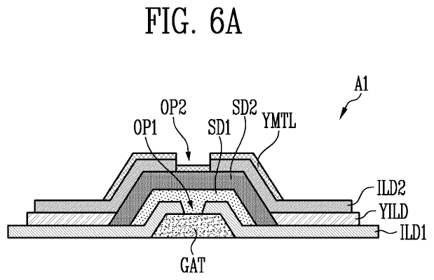

FIG. 5 is a cross-sectional view taken along line I-I′ of FIG. 4 and schematically showing a structure of the pad area according to some example embodiments of the present inventive concepts. FIG. 6A is a cross-sectional view illustrating a first area of FIG. 5 according to some example embodiments of the present inventive concepts. FIG. 6B is a cross-sectional view illustrating a first area of FIG. 5 according to some example embodiments of the present inventive concepts.

Referring to FIG. 5, output pads PD may be arranged on (e.g., directly or indirectly on) a display panel DP. For example, the output pads PD may include first to third output pads PD1 to PD3 that may be arranged on a substrate of the display panel DP. The display panel DP of FIG. 5 may be described similarly to the display panel 15 of FIG. 1. Hereinafter, repetitive descriptions will be omitted.

Bumpers BP may be arranged on (e.g., directly or indirectly on, for example beneath) the controller CON. For example, the bumpers BP may include first to third bumpers BP1 to BP3 that may be arranged on a substrate of the controller CON.

A conductive adhesive film ACF may bond the display panel DP and the controller CON together. For example, the conductive adhesive film ACF may be placed between the output pads PD and the bumpers BP to bond the display panel DP and the controller CON together.

According to some example embodiments, the conductive adhesive film ACF may be a conductive adhesive member, such as an anisotropic conductive film.

According to some example embodiments, the conductive adhesive film ACF may include one or more conductive balls BL and an insulating adhesive member RN. However, the present inventive concepts are not limited thereto.

Each of the conductive balls BL may be a conductive fine particle. A conductive fine particle may conduct electricity, and may be a conductive particle such as a metal or a metal oxide, or a particle having a metal or metal oxide coated on a surface with an insulating material as a core. Examples of the metal included in the conductive ball BL may include nickel (Ni), iron (Fe), copper (Cu), aluminum (Al), tin (Sn), zinc (Zn), chromium (Cr), cobalt (Co), silver (Ag), gold (Au), and the like. However, the present inventive concepts are not limited thereto.

The insulating adhesive member RN may include an insulating polymer. As an insulating polymer, an epoxy resin, an acrylic resin, and the like may be used. However, this is only an example and the insulating adhesive member RN may include another insulating polymer.

The first to third pads PD1 to PD3 may correspond to (e.g., may be overlapped by, for example in a direction perpendicular to the display panel upper surface DPs) the first to third bumpers BP1 to BP3, respectively. For example, the first pad PD1 may be electrically connected to the first bumper BP1 via the conductive balls BL. For example, the second pad PD2 may be electrically connected to the second bumper BP2 via the conductive balls BL. For example, the third pad PD3 may be electrically connected to the third bumper BP3 via the conductive balls BL.

The first to third pads PD1 to PD3 may be arranged adjacent to each other. For example, the first pad PD1 and the second pad PD2 may be arranged adjacent to each other. Additionally, the second pad PD2 and the third pad PD3 may be arranged adjacent to each other.

According to some example embodiments, each of the first to third pads PD1 to PD3 may have a set polarity. For example, each of the first to third pads PD1 to PD3 may receive set output signals, and each of the output signals may have a set polarity.

According to a comparative example, the output signal delivered to the first bumper BP1 may have a positive polarity, and the first pad PD1 may have a positive polarity. Further, the output signal delivered to the second bumper BP2 may have a negative polarity, and the second pad PD2 may have a negative polarity. When the potential difference between signals applied to the first pad PD1 and the second pad PD2 (or applied to the first bumper BP1 and the second bumper BP2) is large, at least a part of the first pad PD1 and the second pad PD2 may be corroded. Accordingly, the electrical resistance of the first pad PD1 and the second pad PD2 may increase, and it is necessary to arrange the pads PD in consideration of polarities of signals applied to the bumpers BP.

Referring to FIG. 6A, a first area A1 may include a gate layer GAT, a first interlayer insulating layer ILD1, a first conductive layer SD1, a vertical interlayer insulating layer YILD, a second conductive layer SD2, a second interlayer insulating layer ILD2, and a vertical metal layer YMTL. The gate layer GAT, the first interlayer insulating layer ILD1, the first conductive layer SD1, the vertical interlayer insulating layer YILD, the second conductive layer SD2, the second interlayer insulating layer ILD2, and the vertical metal layer YMTL may be formed as different layers by different processes.

The first area A1 of FIG. 6A is an area showing a stacked structure of one of the pads PD. However, this is only an example and the first area A1 may further include components not shown in FIG. 6A.

The gate layer GAT may be a layer connected to one of the scan control line GSL or the emission control line ESL of FIG. 4. For example, the gate layer GAT may be configured to deliver an input control signal, which may be either a scan control signal or an emission control signal.

The first interlayer insulating layer ILD1 may be arranged on (e.g., directly or indirectly on) the gate layer GAT. The first interlayer insulating layer ILD1 may be an inorganic insulating layer including an inorganic material. According to some example embodiments, the first interlayer insulating layer ILD1 may be an organic insulating layer including an organic material.

The first interlayer insulating layer ILD1 may include (e.g., may include one or more surfaces defining) a first opening OP1 (or a first via hole). The first opening OP1 may penetrate the first interlayer insulating layer ILD1 and expose the gate layer GAT.

The first conductive layer SD1 may be arranged on (e.g., directly or indirectly on) the first interlayer insulating layer ILD1. The first conductive layer SD1 may be in contact with the gate layer GAT exposed through the first opening OP1. Accordingly, the first conductive layer SD1 and the gate layer GAT may be electrically connected.

The second conductive layer SD2 may be arranged on (e.g., directly or indirectly on) the first conductive layer SD1. The second conductive layer SD2 may be electrically connected to the first conductive layer SD1. Accordingly, the second conductive layer SD2 may be electrically connected to the gate layer GAT.

The vertical interlayer insulating layer YILD may be arranged on (e.g., directly or indirectly on) the first interlayer insulating layer ILD1. The vertical interlayer insulating layer YILD may be arranged adjacent to the second conductive layer SD2 and may be in contact with same. The vertical interlayer insulating layer YILD may be an insulating layer extending in the third direction DR3 (see FIG. 5).

The second interlayer insulating layer ILD2 may be arranged on (e.g., directly or indirectly on) both the vertical interlayer insulating layer YILD and the second conductive layer SD2. The second interlayer insulating layer ILD2 may be an inorganic insulating layer including an inorganic material. According to some example embodiments, the second interlayer insulating layer ILD2 may also be an organic insulating layer including an organic material.

The second interlayer insulating layer ILD2 may include (e.g., may include one or more surfaces defining) a second opening OP2 (or a second via hole). The second opening OP2 may penetrate the second interlayer insulating layer ILD2 and expose the second conductive layer SD2.

The vertical metal layer YMTL may be arranged on (e.g., directly or indirectly on) the second interlayer insulating layer ILD2. The vertical metal layer YMTL may be in contact with the second conductive layer SD2 exposed through the second opening OP2. Accordingly, the vertical metal layer YMTL may be electrically connected to the second conductive layer SD2. The vertical metal layer YMTL may be electrically connected to the gate layer GAT via the second conductive layer SD2 and the first conductive layer SD1.

According to some example embodiments, the conductive ball BL (see FIG. 5) may be in contact with the vertical metal layer YMTL. Accordingly, the conductive ball BL may deliver an electrical signal from the bumpers BP (see FIG. 5) to the vertical metal layer YMTL. For example, the vertical metal layer YMTL may receive an input control signal. Accordingly, the vertical metal layer YMTL may deliver the input control signal to the gate layer GAT, and the gate layer GAT may deliver the input control signal to the scan driver 13 and the emission driver 14.

Referring to FIG. 6B, a first area A1′ may include the gate layer GAT, the first interlayer insulating layer ILD1, the first conductive layer SD1, the vertical interlayer insulating layer YILD, the second conductive layer SD2, the second interlayer insulating layer ILD2, the vertical metal layer YMTL, and a wiring layer UCL. For example, the first area A1′ may further include the wiring layer UCL compared to the first area A1 of FIG. 6A. Hereinafter, repetitive descriptions will be omitted.

The wiring layer UCL may be arranged on (e.g., directly or indirectly on) the back surfaces GATs and ILD1s of the gate layer GAT and the first interlayer insulating layer ILD1. For example, the wiring layer UCL may be a layer which constitutes a base surface of one of the pads PD.

The wiring layer UCL may relatively weaken an electric field generated in the gate layer GAT (or the first area A1′). For example, depending on signals applied to the plurality of pads PD (see FIG. 5), a particular (or, alternatively predetermined) electric field may be formed in each of the plurality of pads PD. Accordingly, the electric field formed in the plurality of pads PD may affect the pads PD adjacent to each other, and the plurality of pads PD may be oxidized or corroded. According to some example embodiments of the present inventive concepts, the wiring layer UCL is arranged on the back surface of the gate layer GAT, so that the electric field formed in the gate layer GAT can be relatively reduced to be delivered to the gate layer GAT of the adjacent pads PD. Accordingly, the plurality of pads PD may be relatively reduced, minimized, or prevented from being oxidized or corroded.

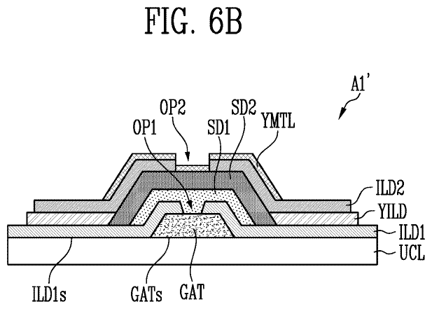

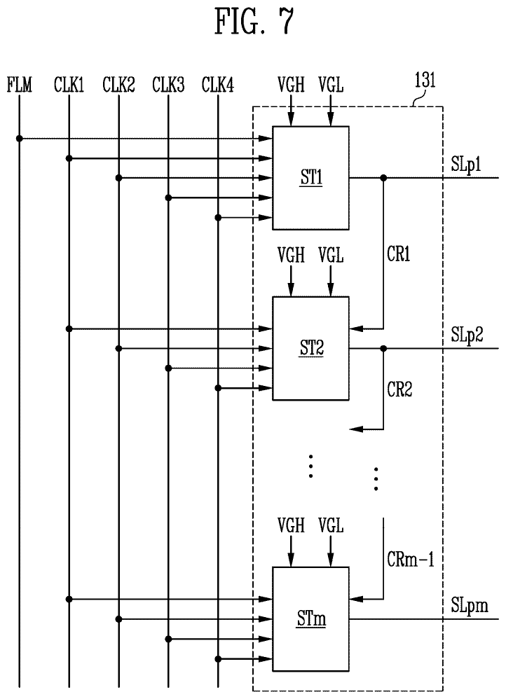

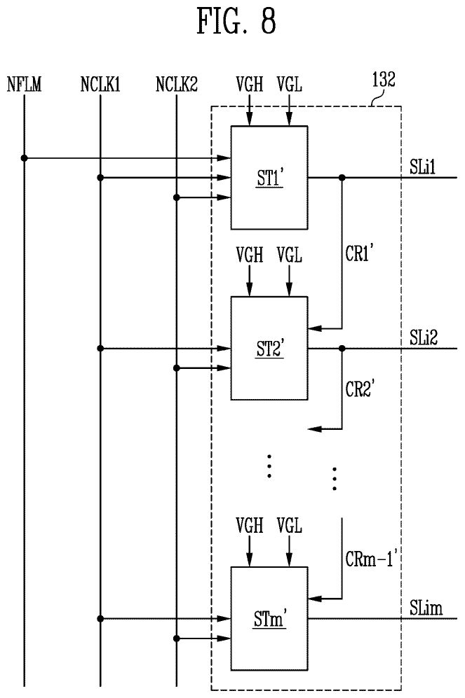

FIG. 7 is a block diagram illustrating a first scan driver 131 which is a component of the scan driver 13 of FIG. 1 according to some example embodiments of the present inventive concepts. FIG. 8 is a block diagram illustrating a second scan driver 132 which is a component of the scan driver 13 of FIG. 1 according to some example embodiments of the present inventive concepts. FIG. 9 is a block diagram illustrating an emission driver 14 of FIG. 1 according to some example embodiments of the present inventive concepts.

First, the first scan driver 131 and the second scan driver 132 respectively shown in FIGS. 7 and 8 may be components of the scan driver 13 of FIG. 1. However, the first scan driver 131 and the second scan driver 132 may be integrated into a single component. Hereinafter, the first scan driver 131 and the second scan driver 132 will be described as separate components for convenience of description. It will be understood that, in some example embodiments, the first scan driver 131 and the second scan driver 132 may be included in a same scan driver 13 of a display device 10.

Referring to FIG. 7, the first scan driver 131 may include first to m-th stages ST1 to STm. The first to m-th stages ST1 to STm may receive a plurality of input control signals. For example, the first stage circuit ST1 may be supplied with a scan start signal FLM, first to fourth clock signals CLK1 to CLK4, first power VGH, and second power VGL. The second stage circuit ST2 may be supplied with a first carry signal CR1, the first to fourth clock signals CLK1 to CLK4, the first power VGH, and the second power VGL. The m-th stage circuit STm may be supplied with an (m−1)-th carry signal CRm−1, the first to fourth clock signals CLK1 to CLK4, the first power VGH, and the second power VGL. However, this is only an example and the present inventive concepts are not limited thereto.

The first scan driver 131 may be configured to provide a scan signal to the p-th scan line SLp of FIG. 1. According to some example embodiments, the scan signal provided to the p-th scan line SLp may be a signal which turns on a gate of the pixel PX (see FIG. 1). The scan signal provided to the p-th scan line SLp may be referred to as a first output signal.

Each of the first to m-th stages ST1 to STm may operate based on the first to fourth clock signals CLK1 to CLK4. The first to fourth clock signals CLK1 to CLK4 may be included in first input control signals. For example, the first to fourth clock signals CLK1 to CLK4 may be the first input control signals on which the first output signal is based.

According to some example embodiments, odd-numbered stages may receive the first and second clock signals CLK1 and CLK2, and even-numbered stages may receive the third and fourth clock signals CLK3 and CLK4.

The scan start signal FLM and first to (m−1)-th carry signals CR1 to CRm−1 are sequentially toggling signals. Accordingly, the scan start signal FLM can be understood as a zeroth carry signal generated before the first carry signal CR1.

In response to the scan start signal FLM, the first stage circuit ST1 may supply a first scan signal to a p1-th scan line SLp1 of the first to m-th scan lines SL1 to SLm. The first scan signal may be provided to the second stage circuit ST2, which is the next stage, as the first carry signal CR1.

The second stage circuit ST2 is configured similarly to the first stage circuit ST1. The second stage circuit ST2 may supply a second scan signal to a p2-th scan line SLp2 of the first to m-th scan lines SL1 to SLm in response to the first carry signal CR1. However, example embodiments are not limited thereto. For example, each stage may include an output circuit which generates a carry signal to be provided to a next stage by delaying a corresponding scan signal.

The m-th stage circuit STm is configured similarly to the second stage circuit ST2. For example, the m-th stage circuit STm may supply an m-th scan signal to a pm-th scan line SLpm of the first to m-th scan lines SL1 to SLm in response to the (m−1)-th carry signal CRm−1. An (m−1)-th scan signal may be provided to the m-th stage circuit STm, which is the next stage, as the (m−1)-th carry signal CRm−1. However, embodiments are not limited thereto. For example, each stage may include an output circuit which generates a carry signal to be provided to a next stage by delaying a corresponding scan signal.

Each of the first to m-th stage circuits ST1 to STm may receive the first power VGH and the second power VGL. The first power VGH has a voltage level capable of turning on transistors of the pixels PX (see FIG. 1) which receive a scan signal. When the transistors of the pixels PX receiving the scan signal are N-type transistors, the first power VGH has a positive voltage level. The second power VGL has a voltage level capable of turning off the transistors of the pixels PX receiving the scan signal. When the transistors of the pixel PX receiving the scan signal are N-type transistors, the second power VGL has a negative voltage level. Hereinafter, for convenience of description, it is assumed that the first power VGH has a positive voltage level and the second power VGL has a negative voltage level. The second power VGL may be lower than the first power VGH.

Referring to FIG. 8, the second scan driver 132 may include first to m-th stages ST1′ to STm′. The first to m-th stages ST1′ to STm′ of FIG. 8 may operate similarly to the first to m-th stages ST1 to STm of FIG. 7.

The first to m-th stages ST1′ to STm′ may receive a plurality of input control signals. For example, the first stage ST1′ may be supplied with an initialization scan start signal NFLM, first and second initialization clock signals NCLK1 and NCLK2, the first power VGH, and the second power VGL. The second stage ST2′ may be supplied with a first carry signal CR1′, the first and second initialization clock signals NCLK1 and NCLK2, the first power VGH, and the second power VGL. The m-th stage STm′ may be supplied with an (m−1)-th carry signal CRm−1′, the first and second initialization clock signals NCLK1 and NCLK2, the first power VGH, and the second power VGL. However, this is only an example and the present inventive concepts are not limited thereto.

The second scan driver 132 may be configured to provide a scan signal to the i-th scan line SLi of FIG. 1. According to some example embodiments, the scan signal provided to the i-th scan line SLi may be a signal which initializes the gate of the pixel PX (see FIG. 1). The scan signal provided to the i-th scan line SLi may be referred to as a third output signal. In some example embodiments, such a scan signal may be referred to as a second output signal.

Each of the first to m-th stages ST1′ to STm′ may operate based on the first and second initialization clock signals NCLK1 and NCLK2. The first and second initialization clock signals NCLK1 and NCLK2 may be included in third input control signals. For example, the first and second initialization clock signals NCLK1 and NCLK2 may be the third input control signals on which the third output signal is based.

According to some example embodiments, odd-numbered stages may receive the first initialization clock signal NCLK1 and even-numbered stages may receive the second initialization clock signal NCLK2.

The initialization scan start signal NFLM and first to (m−1)-th carry signals CR1′ to CRm−1′ are sequentially toggling signals. Accordingly, the initialization scan start signal NFLM can be understood as a zeroth carry signal generated before the first carry signal CR1′.

In response to the initialization scan start signal NFLM, the first stage circuit ST1′ may supply a first initialization scan signal to an i1-th scan line SLi1 of the first to m-th scan lines SL1 to SLm. The first initialization scan signal may be provided to the second stage circuit ST2′, which is the next stage, as the first carry signal CR1′.

The second stage circuit ST2′ is configured similarly to the first stage circuit ST1′. The second stage circuit ST2′ may supply a second initialization scan signal to an i2-th scan line SLi2 of the first to m-th scan lines SL1 to SLm in response to the first carry signal CR1′. However, example embodiments are not limited thereto. For example, each stage may include an output circuit which generates a carry signal to be provided to a next stage by delaying a corresponding scan signal.

The m-th stage circuit STm′ is configured similarly to the second stage circuit ST2′. For example, the m-th stage circuit STm′ may supply an m-th initialization scan signal to an im-th scan line SLim of the first to m-th scan lines SL1 to SLm in response to the (m−1)-th carry signal CRm−1′. An (m−1)-th initialization scan signal may be provided to the m-th stage circuit STm′, which is the next stage, as the (m−1)-th carry signal CRm−1′. However, example embodiments are not limited thereto. For example, each stage may include an output circuit which generates a carry signal to be provided to a next stage by delaying a corresponding scan signal.

Each of the first to m-th stage circuits ST1′ to STm′ may receive the first power VGH and the second power VGL. The first power VGH and the second power VGL of FIG. 8 may be described similarly to the first power VGH and the second power VGL of FIG. 7. Hereinafter, repetitive descriptions will be omitted. However, according to some example embodiments, the first power VGH and the second power VGL of FIG. 8 may have different values than the first power VGH and the second power VGL of FIG. 7.

Referring to FIG. 9, the emission driver 14 may include first to o-th emission stages EST1 to ESTo. The first to o-th emission stages EST1 to ESTo may receive a plurality of input control signals. For example, the first emission stage EST1 may be supplied with an emission start signal ACL_FLM, first and second emission clock signals EM_CLK1 and EM_CLK2, first emission power EVGH, and second emission power EVGL. The second emission stage EST2 may be supplied with a first emission carry signal ECR1, the first and second emission clock signals EM_CLK1 and EM_CLK2, the first emission power EVGH, and the second emission power EVGL. The o-th emission stage ESTo may be supplied with an (o−1)-th emission carry signal ECRo−1, the first and second emission clock signals EM_CLK1 and EM_CLK2, the first emission power EVGH, and the second emission power EVGL. However, this is only an example and the present inventive concepts are not limited thereto.

The emission driver 14 may be configured to provide a light emitting signal to the q-th emission line ELq of FIG. 1. According to some example embodiments, the light emitting signal provided to the q-th emission line ELq may be a signal which causes the pixel PX (see FIG. 1) to emit light (or a signal which controls the emission timing). The light emitting signal provided to the q-th emission line ELq may be referred to as a second output signal. In some example embodiments, the second output signal may be referred to as a third output signal.

Each of the first to o-th emission stages EST1 to ESTo may operate based on the first and second emission clock signals EM_CLK1 and EM_CLK2. The first and second emission clock signals EM_CLK1 and EM_CLK2 may be second input control signals on which the second output signal is based.

According to some example embodiments, odd-numbered emission stages may receive the first emission clock signal EM_CLK1 and even-numbered emission stages may receive the second emission clock signal EM_CLK2.

The emission start signal ACL_FLM and first to (o−1)-th emission carry signals ECR1 to ECRo−1 are sequentially toggling signals. Accordingly, the emission start signal ACL_FLM can be understood as a zeroth emission carry signal generated before the first emission carry signal ECR1.

In response to the emission start signal ACL_FLM, the first emission stage circuit EST1 may supply a first light emitting signal to a q1-th emission line ELq1 of the first to o-th emission lines EL1 to ELo. The first light emitting signal may be provided to the second emission stage circuit EST2, which is the next stage, as the first emission carry signal ECR1.

The second emission stage circuit EST2 is configured similarly to the first emission stage circuit EST1. The second emission stage circuit EST2 may supply a second light emitting signal to a q2-th emission line ELq2 of the first to o-th emission lines EL1 to ELo in response to the first emission carry signal ECR1. However, example embodiments are not limited thereto. For example, each stage may include an output circuit which generates a carry signal to be provided to a next stage by delaying a corresponding light emitting signal.

The o-th emission stage circuit ESTo is configured similarly to the second emission stage circuit EST2. For example, the o-th emission stage circuit ESTo may supply an o-th light emitting signal to a qo-th emission line ELqo of the first to o-th emission lines EL1 to ELo in response to the (o−1)-th emission carry signal ECRo−1. An (o−1)-th light emitting signal may be provided to the o-th emission stage circuit ESTo, which is the next stage, as the (o−1)-th emission carry signal ECRo−1. However, example embodiments are not limited thereto. For example, each stage may include an output circuit which generates a carry signal to be provided to a next stage by delaying a corresponding light emitting signal.

The first emission power EVGH and the second emission power EVGL may be voltages for causing the pixel PX (see FIG. 1) to emit light. For example, the first emission power EVGH has a voltage level which can turn on the transistors connected to the light emitting diode LD (see FIG. 2) of the pixel PX. When transistors of the pixels PX receiving a light emitting signal are N-type transistors, the first emission power EVGH has a positive voltage level. The second emission power EVGL has a voltage level which can turn off the transistors of the pixels PX receiving the light emitting signal. When the transistors of the pixels PX receiving the light emitting signal are N-type transistors, the second emission power EVGL has a negative voltage level. Hereinafter, for convenience of description, it is assumed that the first emission power EVGH has a positive voltage level and the second emission power EVGL has a negative voltage level. The second emission power EVGL (e.g., an absolute magnitude thereof) may be lower than the first emission power EVGH (e.g., an absolute magnitude thereof).

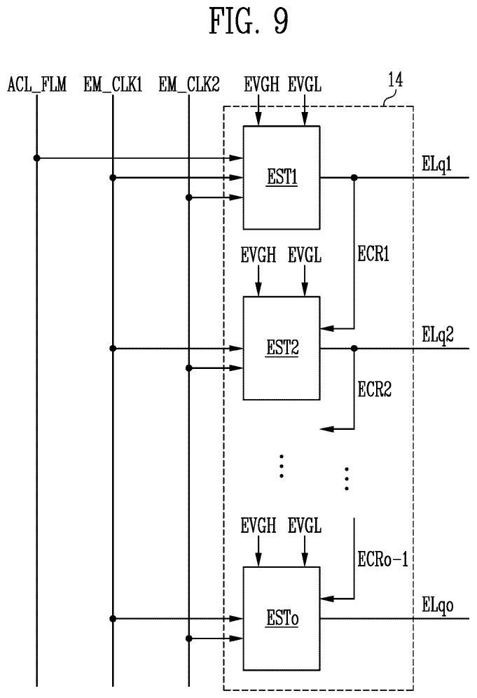

FIG. 10 is a timing diagram showing waveforms of the scan start signal FLM, the initialization scan start signal NFLM, and the emission start signal ACL_FLM according to some example embodiments.

Referring to FIGS. 4 and 10, the controller CON may generate the scan start signal FLM having a gate-on level pulse (e.g., a logic low level). The controller CON may generate the emission start signal ACL_FLM having a gate-off level pulse (e.g., a logic high level). The controller CON may generate the initialization scan start signal NFLM having a gate-off level pulse (e.g., a logic high level).

The controller CON may generate the scan start signal FLM having a gate-on level pulse toggling at least once during each period in which the emission start signal ACL_FLM has a gate-off level pulse.

A period in which the scan start signal FLM has a gate-off level may be a scan period P_GW. For example, the scan period P_GW may be a period during which the first scan driver 131 (see FIG. 7) turns on transistors of pixels connected to the p1-th to pm-th scan lines SLp1 to SLpm (see FIG. 7). According to some example embodiments, the scan period P_GW may be a period during which the pixels operate in a first mode. For example, in the first mode, the second transistor M2 (see FIG. 2) or the third transistor M3 (see FIG. 2) included in the pixel PXij of FIG. 2 may be turned on.

A period during which the emission start signal ACL_FLM has a logic low-level value may be an emission period P_EM. For example, the emission period P_EM may be a period during which the emission driver 14 turns on transistors of pixels connected to the q1-th to qo-th emission lines ELq1 to ELqo (see FIG. 9). According to some example embodiments, the emission period P_EM may be a period during which the pixels operate in a second mode. For example, in the second mode, the fifth transistor M5 (see FIG. 2) or the sixth transistor M6 (see FIG. 2) included in the pixel PXij of FIG. 2 may be turned on, and the light emitting diode LD (see FIG. 2) may be driven.

A period during which the emission start signal ACL_FLM has a logic high-level value and the initialization scan start signal NFLM has a logic high-level value may be a gate initialization period P_GI. For example, the gate initialization period P_GI may be a period during which the second scan driver 132 (see FIG. 8) turns on transistors of pixels connected to the i1-th to im-th scan lines SLi1 to SLim (see FIG. 8). According to some example embodiments, the gate initialization period P_GI may be a period during which the pixels operate in a third mode. For example, in the third mode, the fourth transistor M4 (see FIG. 2) included in the pixel PXij of FIG. 2 may be turned on, and an initialization voltage may be applied to the first node N1.

According to some example embodiments, the scan period P_GW, the emission period P_EM and the gate initialization period P_GI may proceed sequentially. For example, the pixel PX (see FIG. 1) may be sequentially driven in the first mode in which a gate of the pixel PX is turned on, the second mode in which the light emitting diode LD (see FIG. 2) of the pixel PX is driven, and the third mode in which the gate of the pixel PX is initialized.

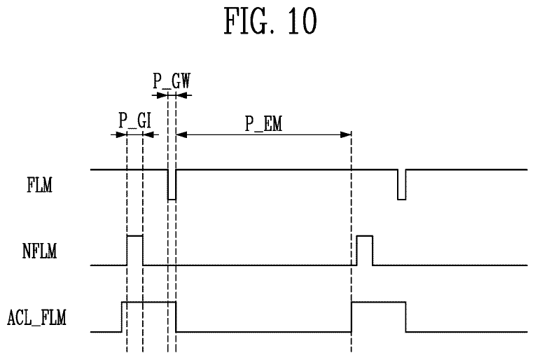

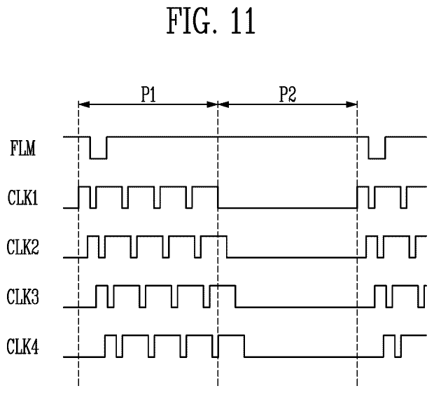

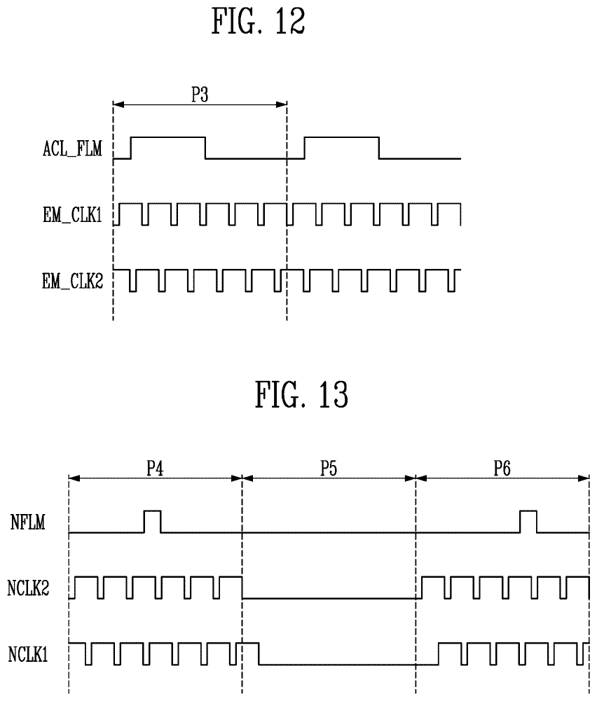

FIG. 11 is a timing diagram showing waveforms of first input control signals according to some example embodiments. FIG. 12 is a timing diagram showing waveforms of second input control signals according to some example embodiments. FIG. 13 is a timing diagram showing waveforms of third input control signals according to some example embodiments.

FIG. 11 illustrates waveforms of the first to fourth clock signals CLK1 to CLK4, which are the first input control signals.

Referring to FIG. 11, the scan start signal FLM and the first to fourth clock signals CLK1 to CLK4 may have a cycle equal to a time interval corresponding to the sum of a first period P1 and a second period P2. However, this is only an example and the present inventive concepts are not limited thereto.

The scan start signal FLM may be synchronized with the first clock signal CLK1 and transition to a logic low level. The logic low-level scan start signal FLM may be set to overlap with the logic low-level first clock signal CLK1 and the logic low-level second clock signal CLK2. Further, the logic low-level scan start signal FLM may be set to not overlap with the logic low-level third clock signal CLK3 and the logic low-level fourth clock signal CLK4.

The second clock signal CLK2 may be set as a signal shifted from the first clock signal CLK1 by a particular (or, alternatively predetermined) period. The third clock signal CLK3 may be set as a signal shifted from the second clock signal CLK2 by a particular (or, alternatively predetermined) period. The fourth clock signal CLK4 may be set to a signal shifted from the third clock signal CLK3 by a particular (or, alternatively predetermined) period.

The first to fourth clock signals CLK1 to CLK4 may be signals which toggle between a logic high level and a logic low level for a time interval equal to the first period P1. For example, the first clock signal CLK1 may switch between a logic high level and a logic low level for a time interval equal to the first period P1.

The first to fourth clock signals CLK1 to CLK4 may maintain the logic low level for a time interval equal to the second period P2 after the time interval equal to the first period P1 during which the first to fourth clock signals CLK1 to CLK4 toggle. According to some example embodiments, the first to fourth clock signals CLK1 to CLK4 may be driven at a low frequency. Accordingly, during one cycle, periods during which the first to fourth clock signals CLK1 to CLK4 have a logic low-level value may be relatively more than periods during which the first to fourth clock signals CLK1 to CLK4 have a logic high-level value. Accordingly, the first to fourth clock signals CLK1 to CLK4 may have a first polarity. According to some example embodiments, the first polarity may be a negative polarity.

The scan start signal FLM may have a logic low-level value in a part of the first period P1. The scan start signal FLM may have a logic high-level value in the remaining part of the first period P1 other than the part. According to some example embodiments, the scan start signal FLM may be driven at a low frequency. During one cycle, periods during which the scan start signal FLM has the logic high-level value may be relatively more than periods during which the scan start signal FLM has the logic low-level value. Accordingly, the scan start signal FLM may have a second polarity. According to some example embodiments, the second polarity may be a positive polarity.

Referring to FIG. 12, the emission start signal ACL_FLM and the first and second emission clock signals EM_CLK1 and EM_CLK2 may have a cycle equal to the third period P3. However, this is only an example and the present inventive concepts are not limited thereto.

FIG. 12 shows the waveforms of the emission start signal ACL_FLM and the first and second emission clock signals EM_CLK1 and EM_CLK2, which are the second input control signals.

The emission start signal ACL_FLM can be synchronized with the second emission clock signal EM_CLK2 and transition to a logic high level. For example, the emission start signal ACL_FLM may transition to the logic high level at the same time point when the second emission clock signal EM_CLK2 transitions to a logic low level.

The first and second emission clock signals EM_CLK1 and EM_CLK2 may be signals which toggle from a logic high level to a logic low level. For example, the first and second emission clock signals EM_CLK1 and EM_CLK2 can switch between the logic high level and the logic low level during the third period P3.

The second emission clock signal EM_CLK2 may be set as a signal shifted from the first emission clock signal EM_CLK1 by a particular (or, alternatively predetermined) period.

During one cycle, periods during which the first and second emission clock signals EM_CLK1 and EM_CLK2 have a logic high-level value may be relatively more than periods during which the first and second emission clock signals EM_CLK1 and EM_CLK2 have a logic low-level value. For example, the first and second emission clock signals EM_CLK1 and EM_CLK2 may be set to have the logic high-level value and then transition to the logic low level, and a period during which the first and second emission clock signals EM_CLK1 and EM_CLK2 have a value transitioned to the logic low level may be relatively short. Accordingly, the first and second emission clock signals EM_CLK1 and EM_CLK2 may have the second polarity.

During one cycle, periods during which the emission start signal ACL_FLM has the logic low level may be relatively more than periods during which the emission start signal ACL_FLM has the logic high level. For example, the emission start signal ACL_FLM may be set to have a logic low-level value and then transition to the logic high level, and a period during which the emission start signal ACL_FLM has a value transitioned to the logic high level may be relatively short. Accordingly, the emission start signal ACL_FLM may have the first polarity.

Referring to FIG. 13, the initialization scan start signal NFLM and the first and second initialization clock signals NCLK1 and NCLK2 may have a cycle equal to a time interval corresponding to the sum of a fourth period P4 and a fifth period P5. However, this is only an example and the present inventive concepts are not limited thereto.

FIG. 13 illustrates the initialization scan start signal NFLM and the first and second initialization clock signals NCLK1 and NCLK2, which are the third input control signals.

The initialization scan start signal NFLM can be synchronized with the first initialization clock signal NCLK1 and transition to a logic high level. The initialization scan start signal NFLM may transition to a logic low level at at least one of time points when the second initialization clock signal NCLK2 transitions from a logic low level to a logic high level.

The second initialization clock signal NCLK2 may be set as a signal shifted from the first initialization clock signal NCLK1 by a particular (or, alternatively predetermined) period.

The first and second initialization clock signals NCLK1 and NCLK2 may be signals which toggle between the logic high level and the logic low level for a time interval equal to the fourth period P4. For example, the second initialization clock signal NCLK2 may switch between the logic high level and the logic low level for the time interval equal to the fourth period P4.

The first and second initialization clock signals NCLK1 and NCLK2 may maintain the logic low level for a time interval equal to the fifth period P5 after a time interval equal to the fourth period P4 during which the first and second initialization clock signals NCLK1 and NCLK2 toggle. According to some example embodiments, the first and second initialization clock signals NCLK1 and NCLK2 may be driven at a low frequency. Accordingly, during one cycle, periods during which the first and second initialization clock signals NCLK1 and NCLK2 have a logic low-level value may be relatively more than periods during which the first and second initialization clock signals NCLK1 and NCLK2 have a logic high-level value. Accordingly, the first and second initialization clock signals NCLK1 and NCLK2 may have the first polarity.

The initialization scan start signal NFLM may have a logic high-level value in a part of the fourth period P4. The initialization scan start signal NFLM may have a logic low-level value in the remaining part of the fourth period P4 other than the part. According to some example embodiments, the initialization scan start signal NFLM may be driven at a low frequency. During one cycle, periods during which the initialization scan start signal NFLM has the logic low-level value may be relatively more than periods during which the initialization scan start signal NFLM has the logic high-level value. Accordingly, the initialization scan start signal NFLM may have the first polarity.

In a sixth period P6, the initialization scan start signal NFLM and the first and second initialization clock signals NCLK1 and NCLK2 may operate similarly to the fourth period P4. Hereinafter, repetitive descriptions will be omitted.

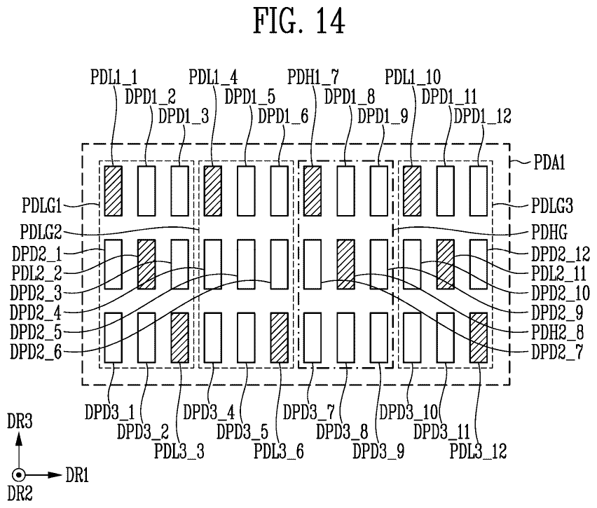

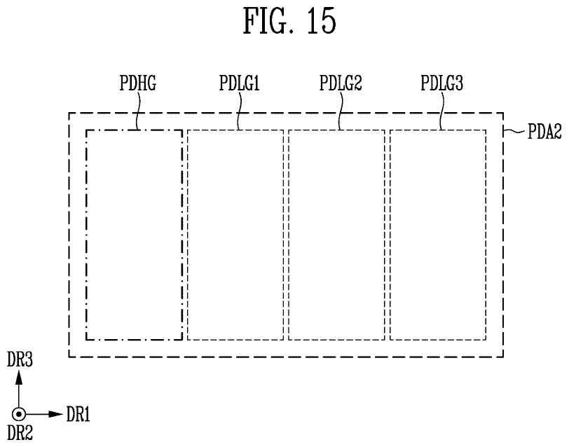

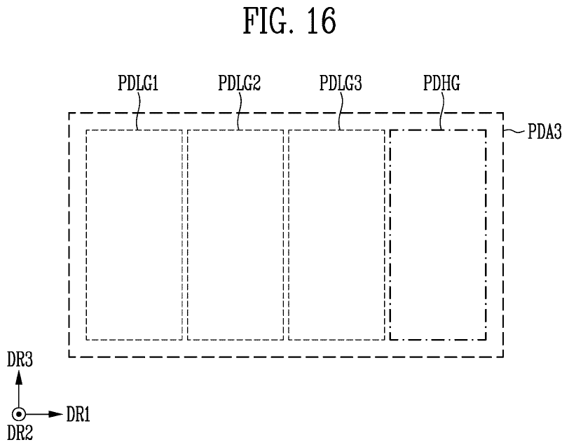

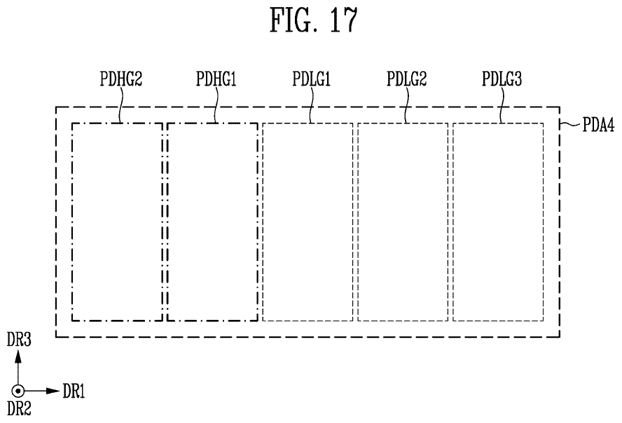

FIG. 14 is a plan view of an example of a pad area according to some example embodiments of the present inventive concepts. FIG. 15 is a plan view of an example of a pad area according to some example embodiments of the present inventive concepts. FIG. 16 is a plan view of an example of a pad area according to some example embodiments of the present inventive concepts. FIG. 17 is a plan view of an example of a pad area according to some example embodiments of the present inventive concepts.

FIG. 14 illustrates a first pad area PDA1, which is an example of the pad area PDA of the display panel 15 of the display device 10 according to some example embodiments, including the example embodiments shown in at least FIGS. 1, 3, and 4 (see FIG. 3). However, this is only an example and the present inventive concepts are not limited thereto. For example, the first pad area PDA1 may be a part of the pad area PDA.

Referring to FIG. 14, the first pad area PDA1 may include pad groups. For example, the first pad area PDA1 may include a (1_1)-th pad group PDLG1, a (1_2)-th pad group PDLG2, a (1_3)-th pad group PDLG3, and a second pad group PDHG. One or more (e.g., all) of the (1_1)-th pad group PDLG1, the (1_2)-th pad group PDLG2, and the (1_3)-th pad group PDLG3 may constitute one or more first pad groups. In the first pad area PDA1, the (1_1)-th pad group PDLG1, the (1_2)-th pad group PDLG2, the second pad group PDHG, and the (1_3)-th pad group PDLG3 may be arranged sequentially in the first direction DR1. Accordingly, at least two first pad groups and the second pad group (the (1_1)-th pad group PDLG1, the (1_2)-th pad group PDLG2, the second pad group PDHG, and the (1_3)-th pad group PDLG3) may be arranged in one direction (e.g., the first direction DR1) so as to be at least partially aligned and/or to at least partially overlap in the one direction (e.g., the first direction DR1), for example as shown in FIGS. 14 to 16.

The (1_1)-th pad group PDLG1, the (1_2)-th pad group PDLG2, and the (1_3)-th pad group PDLG3 may include output pads which deliver (transmit) signals having the first polarity. According to some example embodiments, the first polarity may be the negative polarity. For example, as shown in FIG. 14, the (1_1)-th pad group PDLG1, the (1_2)-th pad group PDLG2, and the (1_3)-th pad group PDLG3 may be referred to as first pad group groups, and the (1_1)-th output pad PDL1_1, the (2_2)-th output pad PDL2_2, and the (3_3)-th output pad PDL3_3 of the (1_1)-th pad group PDLG1, the (1_4)-th output pad PDL1_4 and the (3_6)-th output pad PDL3_6 of the (1_2)-th pad group PDLG2, and the (1_10)-th output pad PDL1_10, the (2_11)-th output pad PDL2_11, and the (3_12)-th output pad PDL3_12 of the (1_3)-th pad group PDLG3 may be referred to as first pad group output pads that are configured to deliver (transmit) first input control signals having a first polarity (e.g., to the scan driver 13). In some example embodiments, the (1_1)-th output pad PDL1_1, the (2_2)-th output pad PDL2_2, and the (3_3)-th output pad PDL3_3 of the (1_1)-th pad group PDLG1 may constitute first output pads of the first pad group output pads, the (1_4)-th output pad PDL1_4 and the (3_6)-th output pad PDL3_6 of the (1_2)-th pad group PDLG2 may constitute second output pads of the first pad group output pads, and the (1_10)-th output pad PDL1_10, the (2_11)-th output pad PDL2_11, and the (3_12)-th output pad PDL3_12 of the (1_3)-th pad group PDLG3 may constitute third output pads of the first pad group output pads.

For example, referring to FIG. 7, in some example embodiments where the scan driver 13 (e.g., including first scan driver 131) is configured to supply (transmit) a first output signal (e.g., a scan signal provided to the p-th scan line SLp) to one or more pixels (e.g., PXij) of the display panel 15, the controller CON may be configured to provide (transmit), to the scan driver 13 via first output pads of the first pad group output pads (e.g., the (1_1)-th output pad PDL1_1, the (2_2)-th output pad PDL2_2, and the (3_3)-th output pad PDL3_3 of the (1_1)-th pad group PDLG1), clock signals on which the first output signal is based (e.g., first to fourth clock signals CLK1 to CLK4), as the first input control signals, such that the scan driver 13 may generate and transmit the first output signal to the display panel 15 based on the clock signals.

In another example, referring to FIG. 8, in some example embodiments where the scan driver 13 (e.g., including second scan driver 132) is configured to supply (transmit) a third output signal (e.g., a scan signal provided to the i-th scan line SLi), also referred to as a second output signal, to one or more pixels (e.g., PXij) of the display panel 15, the controller CON may be configured to provide (transmit), to the scan driver 13 via third output pads of the first pad group output pads (e.g., the (1_10)-th output pad PDL1_10, the (2_11)-th output pad PDL2_11, and the (3_12)-th output pad PDL3_12 of the (1_3)-th pad group PDLG3), also referred to as second output pads of the first pad group output pads, initialization clock signals on which the third (second) output signal is based (e.g., first and second initialization clock signals NCLK1 and NCLK2), as the first input control signals, such that the scan driver 13 may generate and transmit the third (second) output signal to the display panel 15 based on the initialization clock signals.

The second pad group PDHG may include output pads which deliver (transmit) signals having the second polarity. For example, the second pad group PDHG may include a (1_7)-th output pad PDH1_7 and a (2_8)-th output pad PDH2_8 which may be referred to herein as second pad group output pads that are configured to deliver (transmit) second input control signals having the second polarity (e.g., to the emission driver 14). The second polarity may be different from the first polarity. According to some example embodiments, the second polarity may be the positive polarity.

For example, referring to FIG. 9, in some example embodiments where the emission driver 14 is configured to supply (transmit) a second (third) output signal (e.g., a light emitting signal provided to the q-th emission line ELq), to one or more pixels (e.g., PXij) of the display panel 15, the controller CON may be configured to provide (transmit), to the emission driver 14 via output pads of the second pad group output pads (e.g., 1_7)-th output pad PDH1_7 and a (2_8)-th output pad PDH2_8 of the second pad group PDHG), also referred to as first output pads of the second pad group output pads, emission clock signals on which the second (third) output signal is based (e.g., first and second emission clock signals EM_CLK1 and EM_CLK2), as the second input control signals, such that the emission driver 14 may generate and transmit the second (third) output signal to the display panel 15 based on the emission clock signals.

Referring back to FIGS. 3-5, a controller CON may be arranged over the first pad groups (the (1_1)-th pad group PDLG1, the (1_2)-th pad group PDLG2, and the (1_3)-th pad group PDLG3, which may include output pads that constitute the first, second, and third output pads PD1, PD2, and PD3) and the second pad group PDHG, so as to overlap same in a vertical direction perpendicular to an upper surface DPs of the display panel DP. The controller CON may transmit the first and second input control signals to the first and second pad groups to cause the first and second pad groups to transmit the respective first and second input control signals.

Referring back to FIG. 5, in some example embodiments, the controller CON may include bumpers BP that may be in contact with separate, respective output pads of the first pad group output pads and the second pad group output pads.

Referring back to FIGS. 6A and 6B, each output pad of the first pad group output pads and the second output pads may include a gate layer GAT (configured to configured to deliver one of the first input control signals or the second input control signals, a first insulating layer ILD1 on the gate layer GAT and including a first opening OP1 exposing the gate layer GAT, a conductive layer (e.g., first conductive layer SD1 and/or second conductive layer SD2) on the first insulating layer ILD1 and in contact with at least a part of the gate layer GAT, and a metal layer YTML overlapping (e.g., in a vertical direction extending perpendicular to the upper surface DPs of the display panel DP) at least a part of the first conductive layer SD1 and electrically connected to one bumper of the bumpers BP. As shown in FIG. 6B, each output pad may further include a wiring layer UCL on a back surface of the gate layer GAT.

The (1_1)-th pad group PDLG1 may include a (1_1)-th output pad PDL1_1, a (1_2)-th dummy pad DPD1_2, a (1_3)-th dummy pad DPD1_3, a (2_1)-th dummy pad DPD2_1, a (2_2)-th output pad PDL2_2, a (2_3)-th dummy pad DPD2_3, a (3_1)-th dummy pad DPD3_1, a (3_2)-th dummy pad DPD3_2, and a (3_3)-th output pad PDL3_3.

The (1_1)-th output pad PDL1_1, the (2_2)-th output pad PDL2_2, and the (3_3)-th output pad PDL3_3 may be first output pads of the first pad group output pads. Each of the (1_1)-th output pad PDL1_1, the (2_2)-th output pad PDL2_2, and the (3_3)-th output pad PDL3_3 can deliver signals with the same polarity to the scan driver 13 (see FIG. 4). For example, each of the (1_1)-th output pad PDL1_1, the (2_2)-th output pad PDL2_2, and the (3_3)-th output pad PDL3_3 can deliver first input control signals having the first polarity to the scan driver 13 (see FIG. 4).

Referring to FIGS. 11 and 14 together, for example, the (1_1)-th output pad PDL1_1 can deliver the first clock signal CLK1 (see FIG. 11) to the scan driver 13 via the scan control line GSL (see FIG. 4). The (2_2)-th output pad PDL2_2 can deliver the second clock signal CLK2 (see FIG. 11) to the scan driver 13 via the scan control line GSL (see FIG. 4). The (3_3)-th output pad PDL3_3 can deliver the third clock signal CLK3 (see FIG. 11) to the scan driver 13 via the scan control line GSL.

The first output pads of the first pad group output pads may be arranged in different rows and columns in the (1_1)-th pad group PDLG1. For example, in the (1_1)-th pad group PDLG1, the (1_1)-th output pad PDL1_1 may be arranged in the first row and the first column, the (2_2)-th output pad PDL2_2 may be arranged in the second row and the second column, and the (3_3)-th output pad PDL3_3 may be arranged in the third row and the third column. According to some example embodiments of the present inventive concepts, the first output pads are arranged to be relatively spaced apart from one another, so that corrosion or oxidation of other first output pads which is caused by an electric field generated by each of the first output pads can be relatively reduced, minimized, or prevented. Accordingly, the driving reliability of the display device 10 (see FIG. 1), and thus the overall reliability and functionality of the display device 10, may be improved.

The (1_2)-th dummy pad DPD1_2, the (1_3)-th dummy pad DPD1_3, the (2_1)-th dummy pad DPD2_1, the (2_3)-th dummy pad DPD2_3, the (3_1)-th dummy pad DPD3_1, and the (3_2)-th dummy pad DPD3_2 may be dummy pads. For example, the dummy pads may be in a floating state in which the dummy pads do not deliver any signals. However, this is only an example and the present inventive concepts are not limited thereto.

The (1_2)-th pad group PDLG2 may include a (1_4)-th output pad PDL1_4, a (1_5)-th dummy pad DPD1_5, a (1_6)-th dummy pad DPD1_6, a (2_4)-th dummy pad DPD2_4, a (2_5)-th dummy pad DPD2_5, a (2_6)-th dummy pad DPD2_6, a (3_4)-th dummy pad DPD3_4, a (3_5)-th dummy pad DPD3_5, and a (3_6)-th output pad PDL3_6.

Each of the (1_4)-th output pad PDL1_4 and the (3_6)-th output pad PDL3_6 can deliver signals with the same polarity to the scan driver 13 (see FIG. 4). For example, each of the (1_4)-th output pad PDL1_4 and the (3_6)-th output pad PDL3_6 can deliver input control signals having the first polarity to the scan driver 13 (see FIG. 4).

Referring to FIGS. 11, 12, and 14 together, for example, the (1_4)-th output pad PDL1_4 may deliver the fourth clock signal CLK4 (see FIG. 11) to the scan driver 13 via the scan control line GSL (see FIG. 4). The (3_6)-th output pad PDL3_6 can deliver the emission start signal ACL_FLM (see FIG. 12) to the emission driver 14 (see FIG. 4) via the emission control line ESL (see FIG. 4).

In the (1_2)-th pad group PDLG2, the (1_4)-th output pad PDL1_4 may be arranged in the first row and the first column, and the (3_6)-th output pad PDL3_6 may be arranged in the third row and the third column. According to some example embodiments of the present inventive concepts, in the (1_2)-th pad group PDLG2, first output pads might not be arranged in the second row. Accordingly, the (1_4)-th output pad PDL1_4 and the (3_6)-th output pad PDL3_6 are arranged to be relatively spaced apart from each other, so that corrosion or oxidation of the (3_6)-th output pad PDL3_6 which is caused by an electric field generated by the (1_4)-th output pad PDL1_4 may be relatively reduced, minimized, or prevented. Accordingly, the driving reliability of the display device 10 (see FIG. 1), and thus the overall reliability and functionality of the display device 10, may be improved.

The (1_5)-th dummy pad DPD1_5, the (1_6)-th dummy pad DPD1_6, the (2_4)-th dummy pad DPD2_4, the (2_5)-th dummy pad DPD2_5, the (2_6)-th dummy pad DPD2_6, the (3_4)-th dummy pad DPD3_4, and the (3_5)-th dummy pad DPD3_5 may be dummy pads. For example, the dummy pads may be in a floating state in which the dummy pads do not deliver any signals. However, this is only an example and the present inventive concepts are not limited thereto.

According to some example embodiments of the present inventive concepts, one or more dummy pads may be arranged between the output pads. For example, the (1_2)-th dummy pad DPD1_2 and the (1_3)-th dummy pad DPD1_3 may be arranged between the (1_1)-th output pad PDL1_1 of the (1_1)-th pad group PDLG1 and the (1_4)-th output pad PDL1_4 of the (1_2)-th pad group PDLG2 that is adjacent to the(1_1)-th pad group PDLG1 in the first direction DR1. Accordingly, the risk of corrosion of the (1_4)-th output pad PDL1_4 which is caused by the electric field of the (1_1)-th output pad PDL1_1 can be relatively reduced, minimized, or prevented.

According to some example embodiments of the present inventive concepts, the pads (e.g., at least some of the first pad group output pads of the first pad groups and one or more dummy pads of the first pad groups) may be arranged in x rows, where x is an integer of 2 or more. For example, (x−1) dummy pads may be arranged between the (1_1)-th output pad PDL1_1 and the (1_4)-th output pad PDL1_4. For example, when the pads are arranged in four rows, three dummy pads may be arranged between the (1_1)-th output pad PDL1_1 and the (1_4)-th output pad PDL1_4 which are arranged in the same row. However, this is only an example and the present inventive concepts are not limited thereto.

The second pad group PDHG may include a (1_7)-th output pad PDH1_7, a (1_8)-th dummy pad DPD1_8, a (1_9)-th dummy pad DPD1_9, a (2_7)-th dummy pad DPD2_7, a (2_8)-th output pad PDH2_8, a (2_9)-th dummy pad DPD2_9, a (3_7)-th dummy pad DPD3_7, a (3_8)-th dummy pad DPD3_8, and a (3_9)-th dummy pad DPD3_9.

The (1_7)-th output pad PDH1_7 and the (2_8)-th output pad PDH2_8 may be second output pads. The (1_7)-th output pad PDH1_7 and the (2_8)-th output pad PDH2_8 may be referred to as first output pads of the second pad group output pads. Each of the (1_7)-th output pad PDH1_7 and the (2_8)-th output pad PDH2_8 can deliver signals with the same polarity to the emission driver 14 (see FIG. 4). For example, each of the (1_7)-th output pad PDH1_7 and the (2_8)-th output pad PDH2_8 can deliver second input control signals having the second polarity to the emission driver 14, where the second polarity may be different from the first polarity.

Referring to FIGS. 12 and 14 together, for example, the (1_7)-th output pad PDH1_7 can deliver the first emission clock signal EM_CLK1 (see FIG. 12) to the emission driver 14 via the emission control line ESL (see FIG. 4). The (2_8)-th output pad PDH2_8 can deliver the second emission clock signal EM_CLK2 (see FIG. 12) to the emission driver 14 via the emission control line ESL (see FIG. 4).

The second output pads may be arranged in different rows and columns in the second pad group PDHG. For example, in the second pad group PDHG, the (1_7)-th output pad PDH1_7 may be arranged in the first row and the first column, and the (2_8)-th output pad PDH2_8 may be arranged in the second row and the second column. According to some example embodiments of the present inventive concepts, the second output pad may not be arranged in the third row on the second pad group PDHG. Accordingly, the (1_7)-th output pad PDH1_7 and the (2_8)-th output pad PDH2_8 may be arranged to be relatively spaced apart from each other, so that corrosion or oxidation of the (2_8)-th output pad PDH2_8 which is caused by an electric field generated by the (1_7)-th output pad PDH1_7 may be relatively reduced, minimized, or prevented. Accordingly, the driving reliability of the display device 10 (see FIG. 1), and thus the overall reliability and functionality of the display device 10, may be improved.

The (1_8)-th dummy pad DPD1_8, the (1_9)-th dummy pad DPD1_9, the (2_7)-th dummy pad DPD2_7, the (2_9)-th dummy pad DPD2_9, the (3_7)-th dummy pad DPD3_7, the (3_8)-th dummy pad DPD3_8, and the (3_9)-th dummy pad DPD3_9 may be dummy pads. For example, the dummy pads may be in a floating state in which the dummy pads do not deliver any signals. However, this is only an example and the present inventive concepts are not limited thereto.

The (1_3)-th pad group PDLG3 may include a (1_10)-th output pad PDL1_10, a (1_11)-th dummy pad DPD1_11, a (1_12)-th dummy pad DPD1_12, a (2_10)-th dummy pad DPD2_10, a (2_11)-th output pad PDL2_11, a (2_12)-th dummy pad DPD2_12, a (3_10)-th dummy pad DPD3_10, a (3_11)-th dummy pad DPD3_11, and a (3_12)-th output pad PDL3_12.

The (1_10)-th output pad PDL1_10, the (2_11)-th output pad PDL2_11, and the (3_12)-th output pad PDL3_12 may be third output pads. Each of the (1_10)-th output pad PDL1_10, the (2_11)-th output pad PDL2_11, and the (3_12)-th output pad PDL3_12 can deliver signals with the same polarity to the scan driver 13 (see FIG. 4). For example, each of the (1_10)-th output pad PDL1_10, the (2_11)-th output pad PDL2_11, and the (3_12)-th output pad PDL3_12 can deliver third input control signals with the first polarity to the scan driver 13 (see FIG. 4).

Referring to FIGS. 13 and 14 together, for example, the (1_10)-th output pad PDL1_10 can deliver the initialization scan start signal NFLM (see FIG. 13) to the scan driver 13 via the scan control line GSL (see FIG. 4). The (2_11)-th output pad PDL2_11 can deliver the first initialization clock signal NCLK1 (see FIG. 13) to the scan driver 13 via the scan control line GSL. The (3_12)-th output pad PDL3_12 can deliver the second initialization clock signal NCLK2 (see FIG. 13) to the scan driver 13 via the scan control line GSL.

The third output pads may be arranged in different rows and columns in the (1_3)-th pad group PDLG3. For example, in the (1_3)-th pad group PDLG3, the (1_10)-th output pad PDL1_10 may be arranged in the first row and the first column, the (2_11)-th output pad PDL2_11 may be arranged in the second row and the second column, and the (3_12)-th output pad PDL3_12 may be arranged in the third row and the third column. According to some example embodiments of the present inventive concepts, the third output pads are arranged to be relatively spaced apart from one another, so that corrosion or oxidation of other third output pads which is caused by an electric field generated by each of the third output pads can be relatively reduced, minimized, or prevented. Accordingly, the driving reliability of the display device 10 (see FIG. 1), and thus the overall reliability and functionality of the display device 10, may be improved.

According to some example embodiments of the present inventive concepts, the pad groups may be arranged in the first pad area PDA1 in accordance with the temporal sequence of driving modes in which the pixel PX (see FIG. 1) operates. For example, in the first pad area PDA1, the (1_1)-th pad group PDLG1, the (1_2)-th pad group PDLG2, the second pad group PDHG, and the (1_3)-th pad group PDLG3 may be arranged in the first direction DR1. The (1_1)-th pad group PDLG1 may be configured to deliver the first input control signals which drive the pixel PX in the first mode. The second pad group PDHG may be configured to deliver the second input control signals which drive the pixel PX in the second mode. The (1_3)-th pad group PDLG3 may be configured to deliver the third input control signals which drive the pixel PX in the third mode. Accordingly, interference of electrical signals which may occur between the first to third input control signals output from the controller CON (see FIG. 4) may be relatively reduced. On the other hand, according to the comparative example, when output pads delivering first to third input control signals are present in a mixed arrangement in the first pad area PDA1, electrical interference which may occur among the first to third input control signals may be relatively increased. According to some example embodiments of the present inventive concepts, the (1_1)-th pad group PDLG1, in which the first output pads which deliver the first input signals are grouped, the second pad group PDHG, in which the second output pads which deliver the second input signals are grouped, and the (1_3)-th pad group PDLG3, in which the third output pads which deliver the third input signals are grouped, can be arranged sequentially in the first direction DR1. Accordingly, corrosion or oxidation of the output pads may be relatively reduced, and the driving reliability of the display device 10 (see FIG. 1), and thus the overall reliability and functionality of the display device 10, may be improved.

Referring to FIG. 15, a second pad area PDA2, which is an example of the pad area PDA (see FIG. 3) is shown. However, this is only an example and the present inventive concepts are not limited thereto. For example, the second pad area PDA2 may be a part of the pad area PDA.

The second pad area PDA2 may include the second pad group PDHG, the (1_1)-th pad group PDLG1, the (1_2)-th pad group PDLG2, and the (1_3)-th pad group PDLG3. The second pad group PDHG, the (1_1)-th pad group PDLG1, the (1_2)-th pad group PDLG2, and the (1_3)-th pad group PDLG3 of FIG. 15 may be described similarly to the second pad group PDHG, the (1_1)-th pad group PDLG1, the (1_2)-th pad group PDLG2, and the (1_3)-th pad group PDLG3 of FIG. 14. Hereinafter, repetitive descriptions will be omitted.

In the second pad area PDA2, the second pad group PDHG, the (1_1)-th pad group PDLG1, the (1_2)-th pad group PDLG2, and the (1_3)-th pad group PDLG3 may be arranged sequentially in the first direction DR1.

According to some example embodiments of the present inventive concepts, the display device 10 may include a plurality of second pad groups (including the second pad group PDHG), and the first pad groups (e.g., PDLG1, PDLG2, PDLG3, or any combination thereof) may be arranged adjacent to each other, and the second pad groups (including PDHG) may be arranged adjacent to each other. For example, the (1_1)-th pad group PDLG1 and the (1_2)-th pad group PDLG2, each including output pads delivering a signal of the first polarity, may be arranged adjacent to each other in the first direction DR1. Accordingly, the potential difference between the signals applied to the output pads arranged in the (1_1)-th pad group PDLG1 and the (1_2)-th pad group PDLG2 might not be relatively large, and corrosion or oxidation of the output pads of the (1_1)-th pad group PDLG1 and the (1_2)-th pad group PDLG2 may be relatively reduced, minimized, or prevented.

Further, the second pad group PDHG may be arranged adjacent to the (1_1)-th pad group PDLG1 in the opposite direction of the first direction DR1. According to some example embodiments, including example embodiments where the display device 10 includes a plurality of second pad groups including the second pad group PDHG, another (2_1)-th pad group including second output pads delivering signals having the second polarity may be arranged in the second pad area PDA2. The (2_1)-th pad group may be arranged adjacent to the second pad group PDHG in an opposite direction to the direction in which the first pad groups are arranged (e.g., the −DR1 direction). Accordingly, the potential difference between signals applied to the output pads arranged in the second pad group PDHG and the (2_1)-th pad group might not be relatively large, and the corrosion or oxidation of the output pads of the second pad group PDHG and the (2_1)-th pad group may be relatively reduced, minimized, or prevented.

Referring to FIG. 16, a third pad area PDA3, which is an example of the pad area PDA (see FIG. 3) is shown. However, this is only an example and the present inventive concepts are not limited thereto. For example, the third pad area PDA 3 may be a part of the pad area PDA.

The third pad area PDA3 may include the (1_1)-th pad group PDLG1, the (1_2)-th pad group PDLG2, the (1_3)-th pad group PDLG3, and the second pad group PDHG. The (1_1)-th pad group PDLG1, the (1_2)-th pad group PDLG2, the (1_3)-th pad group PDLG3, and the second pad group PDHG of FIG. 16 may be described similarly to the (1_1)-th pad group PDLG1, the (1_2)-th pad group PDLG2, the (1_3)-th pad group PDLG3, and the second pad group PDHG of FIG. 14. Hereinafter, repetitive descriptions will be omitted.

In the third pad area PDA3, the (1_1)-th pad group PDLG1, the (1_2)-th pad group PDLG2, the (1_3)-th pad group PDLG3, and the second pad group PDHG may be arranged sequentially in the first direction DR1.

Referring to FIG. 17, a fourth pad area PDA4, which is an example of the pad area PDA (see FIG. 3) is shown. However, this is only an example and the present inventive concepts are not limited thereto. For example, the fourth pad area PDA 4 may be a part of the pad area PDA.

Referring to FIG. 17, according to some example embodiments of the present inventive concepts, the display device 10 may include a plurality of second pad groups (e.g., PDHG1 and PDHG2), and a plurality of first pad groups (e.g., PDLG1, PDLG2, PDLG3, or any combination thereof). The second pad group PDHG2, also referred to herein as a (2_1)-th pad group, may have a similar structure as the second pad group PDHG1, and descriptions herein of a structure of the second pad group PDHG1 will be understood to apply equally to the second pad group PDHG2.

The second pad group PDHG1 may be arranged adjacent to the (1_1)-th pad group PDLG1 in the opposite direction of the first direction DR1, and the (2_1)-th pad group PDHG2 including second output pads delivering signals having the second polarity may be arranged in the fourth pad area PDA4 and may be arranged adjacent to the second pad group PDHG1 in the opposite direction to the direction in which the first pad groups are arranged (e.g., the −DR1 direction). Accordingly, the potential difference between signals applied to the output pads arranged in the second pad group PDHG1 and the (2_1)-th pad group PDHG2 might not be relatively large, and the corrosion or oxidation of the output pads of the second pad group PDHG1 and the (2_1)-th pad group PDHG2 may be relatively reduced, minimized, or prevented.

As shown in FIG. 17, the first pad groups e.g., PDLG1, PDLG2, PDLG3, or any combination thereof) may be arranged adjacent to each other, and the second pad groups (e.g., PDHG1 and PDHG2) may be arranged adjacent to each other. Accordingly, the potential difference between the signals applied to the output pads arranged in the (1_1)-th pad group PDLG1 and the (1_2)-th pad group PDLG2 might not be relatively large, and corrosion or oxidation of the output pads of the (1_1)-th pad group PDLG1 and the (1_2)-th pad group PDLG2 may be relatively reduced, minimized, or prevented.

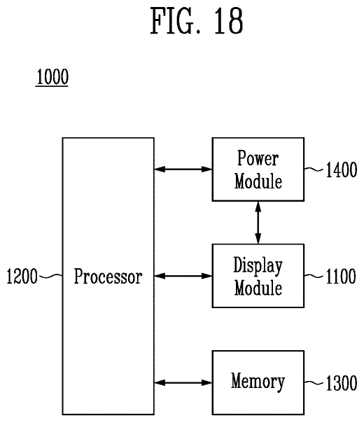

FIG. 18 is a block diagram of an electronic device 1000 according to some example embodiments of the present inventive concepts. Referring to FIG. 18, the electronic device 1000 according to some example embodiments may include a display module 1100, a processor 1200, memory 1300, and a power module 1400. The display module 1100 of FIG. 18 may be described similarly to the display device 10 of FIG. 1. For example the display module 1100 may include the display device 10.

The processor 1200 may include at least one of a central processing unit (CPU), an application processor (AP), a graphics processing unit (GPU), a communication processor (CP), an image signal processor (ISP), and a controller.

The memory 1300 may store data information used for an operation of the processor 1200 or the display module 1100 (also referred to herein as a display device). In an example in which the processor 1200 executes the application stored in the memory 1300, an image data signal and/or an input control signal are delivered to the display module 1100, and the display module 1100 may process the received signal and output image information through a display screen.

The power module 1400 (also referred to herein as a power supply, a power supply device, a power device, or the like) may include a power supply module, such as a power adapter or a battery device, and a power conversion module which converts power supplied by the power supply module to generate power used for an operation of the electronic device 1000.

At least one of the above-described components of the electronic device 1000 may be included in the display device according to the above-described embodiments. In some aspects, one or more of individual modules which are functionally included in one module may be included in the display device, and individual modules other than the one or more of the individual modules may be provided separately from the display device. For example, the display device may include the display module 1100, and the processor 1200, the memory 1300, and the power module 1400 may be provided in the form of other devices in the electronic device 1000 other than the display device.

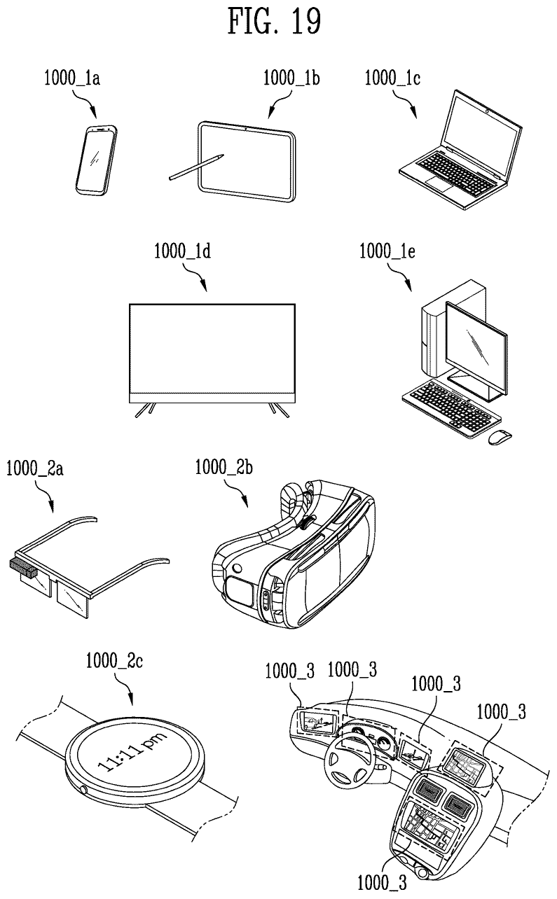

FIG. 19 illustrates schematic diagrams of an electronic device according to some example embodiments of the present inventive concepts.

Referring to FIG. 19, examples of various electronic devices to which the display device according to some example embodiments of the present inventive concepts may include electronic devices for displaying images, such as a smartphone 1000_1a, a tablet PC 1000_1b, a laptop 1000_1c, a television 1000_1d, or a desk monitor 1000_1e, as well as wearable electronic devices including display modules, such as smart glasses 1000_2a, a head-mounted display 1000_2b, or a smart watch 1000_2c, and automotive electronic devices 1000_3 including the display modules 1100, such as an automotive dashboard, a center fascia, a Center Information Display (CID) placed on a dashboard, or a room mirror display. According to some example embodiments, the display device 10 (see FIG. 1) can be implemented as an automotive dashboard, a center fascia, a CID placed on a dashboard, or a room mirror display.

As described herein, any devices, systems, modules, portions, units, controllers, circuits, and/or portions thereof according to any of the example embodiments, and/or any portions thereof (including, without limitation, display device 10, timing controller 11, data driver 12, scan driver 13, emission driver 14, display panel 15, controller CON, electronic device 1000, processor 1200, memory 1300, display module 1100, power module 1400, smartphone 1000_1a, tablet PC 1000_1b, laptop 1000_1c, television 1000_1d, desk monitor 1000_1e, smart glasses 1000_2a, head-mounted display 1000_2b, smart watch 1000_2c, automotive electronic devices 1000_3, any portion thereof, or the like) may include, may be included in, and/or may be implemented by one or more instances of processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a graphics processing unit (GPU), an application processor (AP), a digital signal processor (DSP), a microcomputer, a field programmable gate array (FPGA), and programmable logic unit, a microprocessor, application-specific integrated circuit (ASIC), a neural network processing unit (NPU), an Electronic Control Unit (ECU), an Image Signal Processor (ISP), and the like. In some example embodiments, the processing circuitry may include a non-transitory computer readable storage device (e.g., a memory), for example a solid state drive (SSD), storing a program of instructions, and a processor (e.g., CPU) configured to execute the program of instructions to implement the functionality and/or methods performed by some or all of any devices, systems, modules, portions, units, controllers, circuits, and/or portions thereof according to any of the example embodiments.

Although specific example embodiments and applications have been described herein, other example embodiments and variations may be derived from the above descriptions. Accordingly, the spirit of the present inventive concepts is not limited to such specific example embodiments and applications, but extends to the appended claims, various obvious modifications, and equivalents.

According to some example embodiments of the present inventive concepts, a display device and electronic device with improved driving reliability by reducing, minimizing, or preventing corrosion of output pads arranged on a display panel may be provided. Accordingly, the reliability and thus the functionality of the display panel and any display device, electronic device, or the like including same may be improved.

However, the effects according to some example embodiments of the present inventive concepts are not limited to the effects described above, and wider variety of effects are included herein.

What is claimed is:

1. A display device, comprising:
a display panel, the display panel including one or more pixels, the one or more pixels configured to display an image based on receiving output signals;
first pad groups, the first pad groups including first pad group output pads, the first pad group output pads configured to deliver first input control signals having a first polarity;
second pad groups, the second pad groups including second pad group output pads, the second pad group output pads configured to deliver second input control signals having a second polarity, the second polarity different from the first polarity; and
a controller overlapping the first pad groups and the second pad groups in a vertical direction perpendicular to an upper surface of the display panel, the controller configured to provide the first input control signals and the second input control signals,
wherein the first pad groups are adjacent to each other, and the second pad groups are adjacent to each other.

2. The display device according to claim 1, further comprising:
a scan driver configured to supply a first output signal of the output signals to the display panel,
wherein the controller is configured to provide, to the scan driver via first output pads of the first pad group output pads, clock signals on which the first output signal is based, as the first input control signals.

3. The display device according to claim 2, wherein
the scan driver is configured to supply a second output signal of the output signals to the display panel, and
the controller is configured to provide, to the scan driver via second output pads of the first pad group output pads, initialization clock signals on which the second output signal is based, as the first input control signals.

4. The display device according to claim 3, further comprising:
an emission driver configured to supply a third output signal of the output signals,
wherein the controller is configured to provide, to the emission driver via first output pads of the second pad group output pads, emission clock signals on which the third output signal is based, as the second input control signals.

5. The display device according to claim 4, wherein
the first output pads of the first pad group output pads are in different rows and columns in one first pad group of the first pad groups,
the first output pads of the second pad group output pads are in different rows and columns in one second pad group of the second pad groups, and
the second output pads of the first pad group output pads are in different rows and columns in another first pad group of the first pad groups.

6. The display device according to claim 1, wherein the first pad groups and the second pad groups are arranged in one direction.

7. The display device according to claim 6, wherein the first pad groups include:
a (1_1)-th pad group and a (1_2)-th pad group adjacent to each other in the one direction; and
one or more dummy pads between a (1_1)-th output pad of the (1_1)-th pad group and a (1_4)-th output pad of the (1_2)-th pad group, with respect to the one direction.

8. The display device according to claim 7, wherein
the first pad group output pads and the one or more dummy pads are arranged in x rows, where x is an integer of 2 or more, and
(x−1) dummy pads of the one or more dummy pads are between the (1_1)-th output pad and the (1_4)-th output pad.

9. The display device according to claim 7, wherein
the second pad groups include a (2_1)-th pad group adjacent to the (1_1)-th pad group in an opposite direction of the one direction, and
the one or more dummy pads are between the (1_1)-th output pad and a (1_7)-th output pad of the (2_1)-th pad group, with respect to the one direction.

10. The display device according to claim 1, wherein the controller includes bumpers in contact with separate, respective output pads of the first pad group output pads and the second pad group output pads.

11. The display device according to claim 10, wherein each output pad of the first pad group output pads and the second pad group output pads comprises:
a gate layer configured to deliver one of the first input control signals or the second input control signals;
a first insulating layer on the gate layer, the first insulating layer including an opening, the opening exposing the gate layer;
a conductive layer on the first insulating layer, the conductive layer in contact with at least a part of the gate layer; and
a metal layer overlapping at least a part of the conductive layer, the metal layer electrically connected to one bumper of the bumpers.

12. The display device according to claim 11, wherein each output pad of the first pad group output pads and the second pad group output pads further comprises a wiring layer on a back surface of the gate layer.

13. A display device, comprising:
a display panel, the display panel including one or more pixels, the one or more pixels configured to display an image based on receiving output signals, the output signals including a first output signal, a second output signal, and a third output signal;
a scan driver configured to supply the first output signal and the third output signal to the display panel;
an emission driver configured to supply the second output signal to the display panel;
a first pad group including first output pads, the first output pads configured to deliver first input control signals to the scan driver based on the first output signal;
a second pad group including second output pads, the second output pads configured to deliver second input control signals to the emission driver based on the second output signal; and
a third pad group including third output pads, the third output pads configured to deliver third input control signals to the scan driver based on the third output signal,
wherein the one or more pixels are configured to operate in a first mode, a second mode, and a third mode sequentially according to the first output signal, the second output signal, and the third output signal, and
wherein the first pad group, the second pad group, and the third pad group are arranged in one direction.

14. The display device according to claim 13, wherein
the first input control signals and the third input control signals have a first polarity, and
the second input control signals have a second polarity, the second polarity different from the first polarity.

15. The display device according to claim 13, wherein
the first output pads are in different rows and columns in the first pad group,
the second output pads are in different rows and columns in the second pad group, and
the third output pads are in different rows and columns in the third pad group.

16. The display device according to claim 13, wherein the first pad group includes one or more dummy pads arranged adjacent to one of the first output pads in the one direction.

17. The display device according to claim 16, wherein
in the first pad group, the first output pads and the one or more dummy pads are arranged in x rows, where x is an integer of 2 or more, and
(x−1) dummy pads of the one or more dummy pads are between the first output pads, with respect to the one direction.

18. An electronic device, comprising:
a processor configured to provide input image data; and
a display device configured to display an image based on the input image data,
wherein the display device includes
a display panel, the display panel including one or more pixels, the one or more pixels configured to display the image based on receiving output signals,
first pad groups, the first pad groups including first pad group output pads, the first pad group output pads configured to deliver first input control signals having a first polarity,
second pad groups, the second pad groups including second pad group output pads, the second pad group output pads configured to deliver second input control signals having a second polarity, the second polarity different from the first polarity, and
a controller overlapping the first pad groups and the second pad groups in a vertical direction perpendicular to an upper surface of the display panel, the controller configured provide the first input control signals and the second input control signals, and
wherein the first pad groups are adjacent to each other, and the second pad groups are adjacent to each other.
